(19) United States
(12) Patent Application Publication
(10) Pub. No.: US 2020/0106028 A1
(43) Pub. Date: Apr. 2, 2020

(54) IRIDIUM COMPLEX AND ORGANIC ELECTROLUMINESCENCE DEVICE USING THE SAME

(71) Applicants: FENG-WEN YEN, TAIPEI (TW); TSUN-YUAN HUANG, CHIAYI (TW)

(72) Inventors: FENG-WEN YEN, TAIPEI (TW); TSUN-YUAN HUANG, CHIAYI (TW)

(73) Assignee: LUMINESCENCE TECHNOLOGY CORPORATION, HSINCHU (TW)

(21) Appl. No.: 16/147,899

(22) Filed: Oct. 1, 2018

(51) Int. Cl. H01L 51/00; C07F 15/00; C09K 11/06

(52) U.S. Cl. CPC H01L 51/0085; H01L 51/5016; C09K 11/06; C07F 15/0033

(57) ABSTRACT

The present invention discloses an iridium complex of formula (1) and an organic electroluminescence device employing the iridium complex as the phosphorescent dopant material. The organic EL device can display good performance, such as lower driving voltage, reduced power consumption, increased efficiency, and longer half-life time.

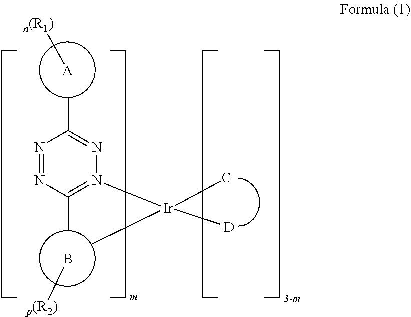

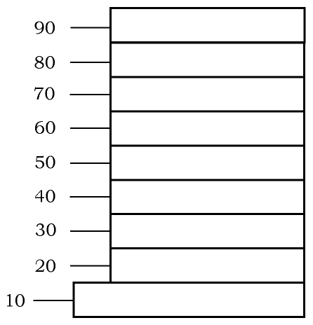

### FIELD OF INVENTION

The present invention relates generally to an iridium complex, and, more specifically, to an organic electroluminescence (hereinafter referred to as organic EL) device using the iridium complex.

### BACKGROUND OF THE INVENTION

An organic EL device is a light-emitting diode (LED) in which the light emitting layer is a film made from organic compounds, which emits light in response to an electric current. The light emitting layer containing the organic compound is sandwiched between two electrodes. The organic EL device is applied to flat panel displays due to its high illumination, low weight, ultra-thin profile, self-illumination without back light, low power consumption, wide viewing angle, high contrast, simple fabrication methods and rapid response time.

The first observation of electroluminescence in organic materials was in the early 1950s by Andre Bernanose and his co-workers at the Nancy-University in France. Martin Pope and his co-workers at New York University first observed direct current (DC) electroluminescence on a single pure crystal of anthracene and on anthracene crystals doped with tetracene under vacuum in 1963. The first diode device was created by Ching W. Tang and Steven Van Slyke at Eastman Kodak in 1987. The diode device used a two-layer structure with separate hole transporting and electron transporting layers, resulting in reduction of operating voltage and improvement of the efficiency, thereby leading to the current era of organic EL research and device production.

Typically, organic EL device is composed of organic material layers sandwiched between two electrodes. The organic material layers include the hole transporting layer, the light emitting layer, and the electron transporting layer. The basic mechanism of organic EL involves the injection, transport, and recombination of carriers as well as exciton formation for emitting light. When an external voltage is applied across the organic EL device, electrons and holes are injected from the cathode and the anode, respectively. Electrons will be injected from a cathode into a LUMO (lowest unoccupied molecular orbital) and holes will be injected from an anode into a HOMO (highest occupied molecular orbital). Subsequently, the electrons recombine with holes in the light emitting layer to form excitons and then emit light. When luminescent molecules absorb energy to achieve an excited state, the exciton may either be in a singlet state or a triplet state, depending on how the spins of the electrons and holes have been combined. 75% of the excitons is formed by recombination of electrons and holes to achieve the triplet excited state. Decay from triplet states is spin forbidden, thus, a fluorescence electroluminescent device has only 25% internal quantum efficiency. In contrast to fluorescence electroluminescent device, phosphorescent organic EL device make use of spin-orbit interactions to facilitate intersystem crossing between singlet and triplet states, thus obtaining emission from both singlet and triplet states and the internal quantum efficiency of electroluminescent devices from 25% to 100%. The spin-orbit interactions is achieved by certain heavy atoms, such as iridium, rhodium, platinum, and palladium, and the phosphorescent transition may be observed from an excited MLCT (metal to ligand charge transfer) state of organic metallic complexes.

The phosphorescent organic EL device utilizes both triplet and singlet excitions. Cause of longer lifetime and diffusion length of triplet excitions compared to those of singlet excitions, the phosphorescent organic EL device generally need an additional hole blocking layer (HBL) between the emitting layer (EML) and the electron transporting layer (ETL) or an electron blocking layer (EBL) between the emitting layer (EML) and the hole transporting layer (HTL). The purpose of the use of HBL or EBL is to confine the recombination of injected holes and electrons and the relaxation of created excitons within the EML, hence the device's efficiency can be improved. To meet such roles, the hole blocking materials or the electron blocking materials must have HOMO (highest occupied molecular orbital) and LUMO (lowest unoccupied molecular orbital) energy levels suitable to block hole or electron transport from the EML to the ETL or the HTL.

For full-colored flat panel displays in AMOLED or OLED lighting field, the conventional materials used for the phosphorescent dopant in light emitting layer, such as the metallic complexes, are still unsatisfactory in driving voltage, current efficiency and half-life time, and still have disadvantages for industrial practice use.

### SUMMARY OF THE INVENTION

According to the reasons described above, the present invention has the objective of resolving the problems of prior arts and offering an organic EL device, which has high current efficiency and long half-life time. The present invention discloses an iridium complex, which is used as a phosphorescent dopant to lower driving voltage and power consumption and increase current efficiency and half-life time of organic EL devices. The iridium complex exhibits good thermal stability in the process for producing the organic EL device.

The present invention has the economic advantages for industrial practice. Accordingly, the present invention discloses an iridium complex which can be used in organic EL devices. The mentioned iridium complex is represented by the following formula (1):

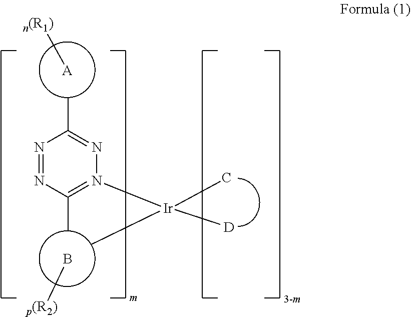

wherein C-D represents a bidentate ligand; ring A and ring B independently represent a fused ring unit with one to five rings; m represents an integer of 1 to 3; n and p independently represent an integer of 1 to 4; R₁ to R₂ are independently a hydrogen atom, a halogen, NO₂, a substituted or unsubstituted alkyl group having 1 to 30 carbon atoms, a substituted or unsubstituted alkoxy group having 1 to 30 carbon atoms, a substituted or unsubstituted aryl group having 6 to 30 carbon atoms, a substituted or unsubstituted aralkyl group having 6 to 30 carbon atoms, or a substituted or unsubstituted heteroaryl group having 3 to 30 carbon atoms.

The present invention further discloses an organic electroluminescence device. The organic electroluminescence device comprises a pair of electrodes composed of a cathode and an anode, and a light emitting layer between the pair of electrodes. The light emitting layer comprises the iridium complex of formula (1).

### BRIEF DESCRIPTION OF THE DRAWINGS

The FIGURE is a schematic view showing an organic EL device according to an embodiment of the present invention.

### DESCRIPTION OF THE PREFERRED EMBODIMENTS

What probed into the invention is the iridium complex and organic EL device using the iridium complex. Detailed descriptions of the production, structure and elements will be provided as follows such that the invention can be fully understood. Obviously, the application of the invention is not confined to specific details familiar to those skilled in the art. On the other hand, the common elements and procedures that are well known are not described in details to avoid unnecessary limits of the invention. Some preferred embodiments of the present invention will now be described in greater detail as follows. However, it should be recognized that the present invention can be practiced in a wide range of other embodiments besides those explicitly described, that is, this invention can also be applied extensively to other embodiments, and the scope of the present invention is expressly not limited except as specified in the accompanying claims.

In one embodiment of the present invention, an iridium complex which can be used as phosphorescent dopant material of light emitting layer for organic EL device is disclosed. The iridium complex is represented by the following formula(1):

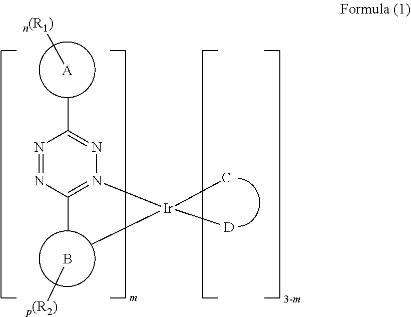

wherein C-D represents a bidentate ligand; ring A and ring B independently represent a fused ring unit with one to five rings; m represents an integer of 1 to 3; n and p independently represent an integer of 1 to 4; R₁ to R₂ are independently a hydrogen atom, a halogen, NO₂, a substituted or unsubstituted alkyl group having 1 to 30 carbon atoms, a substituted or unsubstituted alkoxy group having 1 to 30 carbon atoms, a substituted or unsubstituted aryl group having 6 to 30 carbon atoms, a substituted or unsubstituted aralkyl group having 6 to 30 carbon atoms, or a substituted or unsubstituted heteroaryl group having 3 to 30 carbon atoms.

In some embodiments, the bidentate ligand has one of the following formulas:

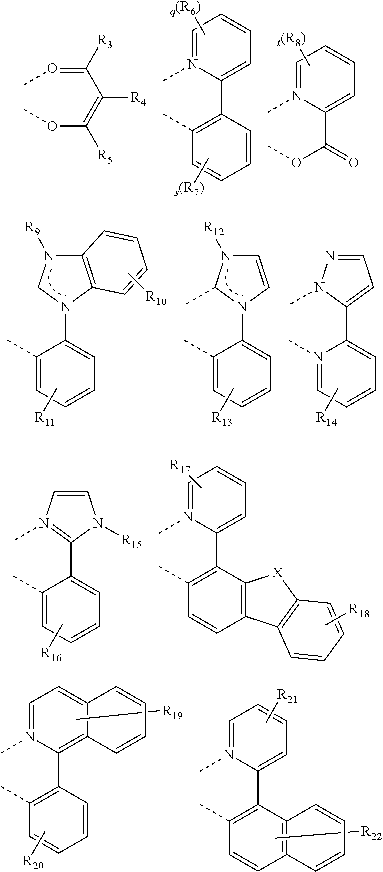

wherein X represents O, S, Se, CR₂₃R₂₄, NR₂₅ or SiR₂₆R₂₇; q, s, and t independently represent an integer of 1 to 4; and R₃ to R₂₇ are independently a hydrogen atom, a halogen, a substituted or unsubstituted alkyl group having 1 to 30 carbon atoms, a substituted or unsubstituted cycloalkyl group having 1 to 30 carbon atoms, a substituted or unsubstituted aryl group having 6 to 30 carbon atoms, a substituted or unsubstituted aralkyl group having 6 to 30 carbon atoms, or a substituted or unsubstituted heteroaryl group having 3 to 30 carbon atoms.

In certain embodiments, R₃ to R₂₂ are independently a hydrogen atom, a methyl group, an isopropyl group, an isobutyl group, a cyclopentyl group, a hexyl group, a cyclohexyl group, or a phenyl group.

In some embodiments, ring A and ring B independently represent a phenyl group, a naphthyl group, a anthracenyl group, a phenanthrenyl group, a pyrenyl group, a chrysenyl group, a triphenylenyl group, a perylenyl group, an imidazole group, a pyridine group, an isoquinoline group, a thiophenyl group, or a benzothiophenyl group.

Preferably, the iridium complex is one of the following compounds:

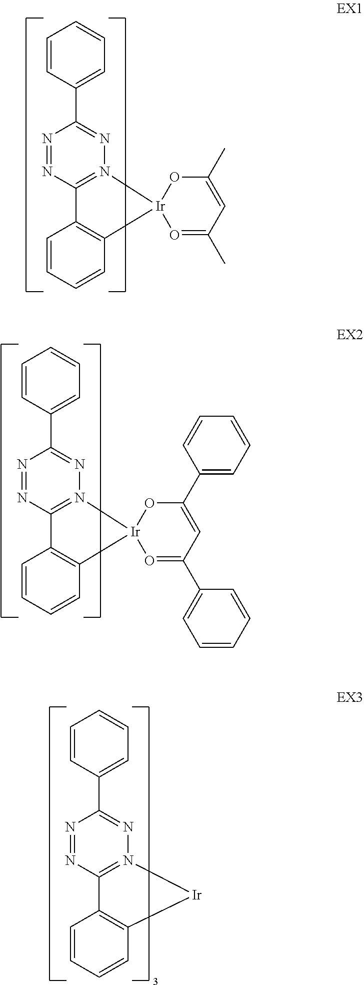

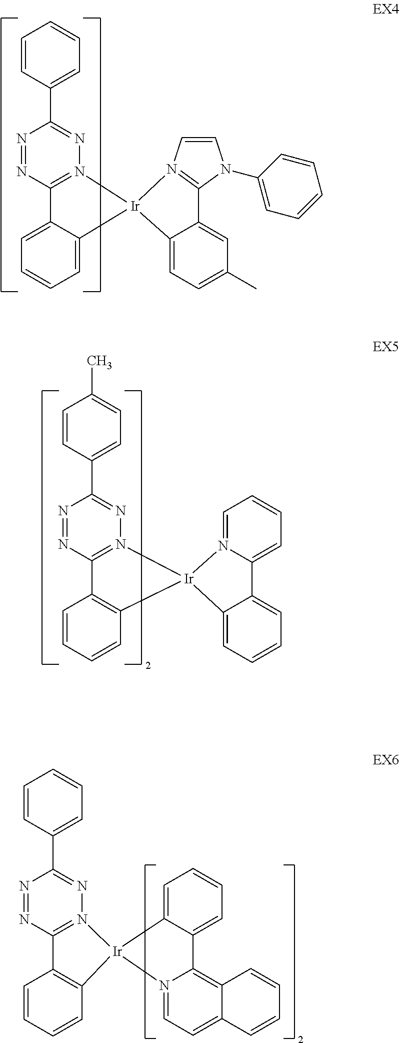

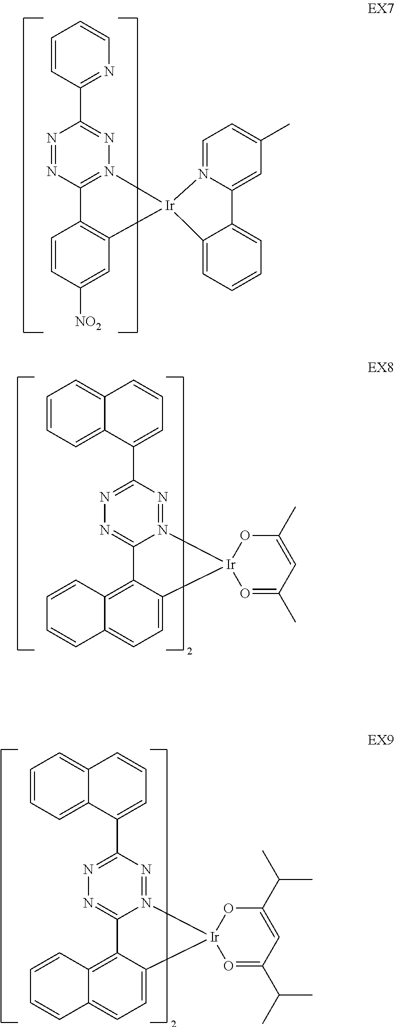

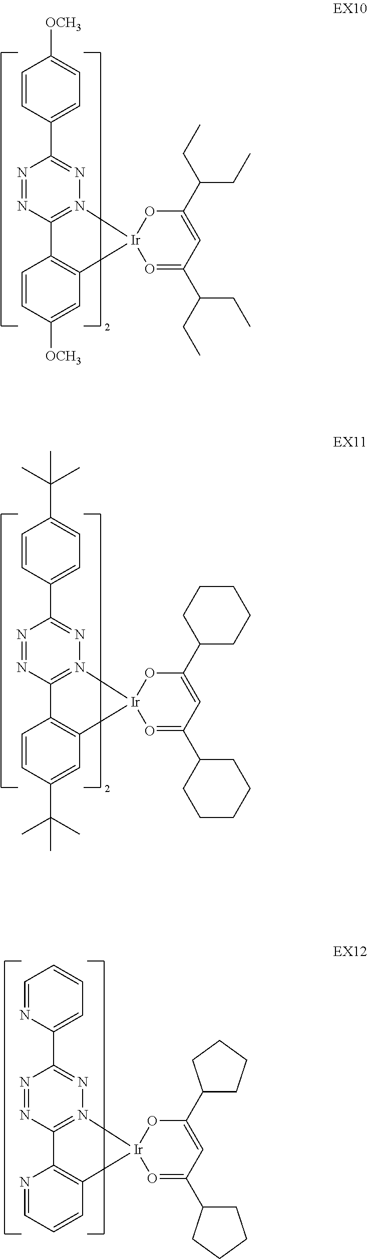

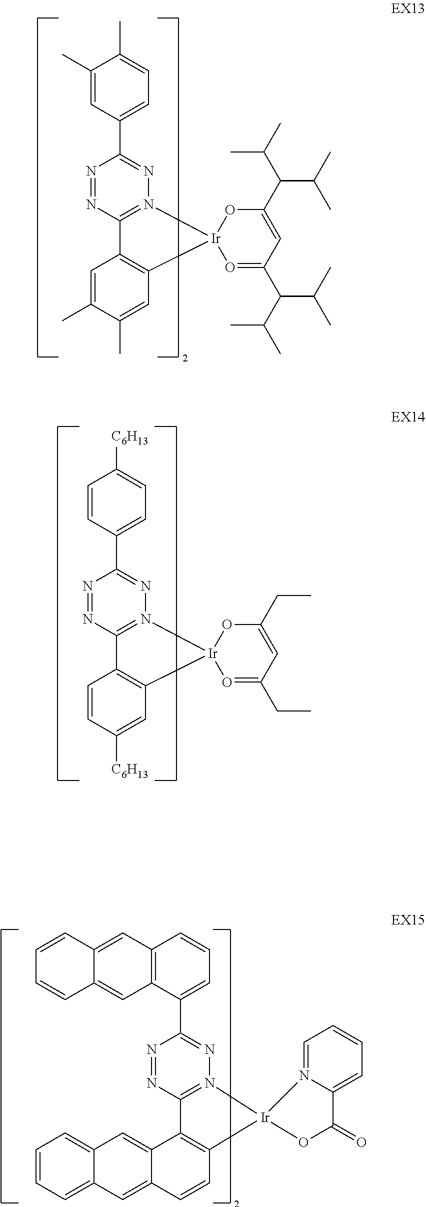

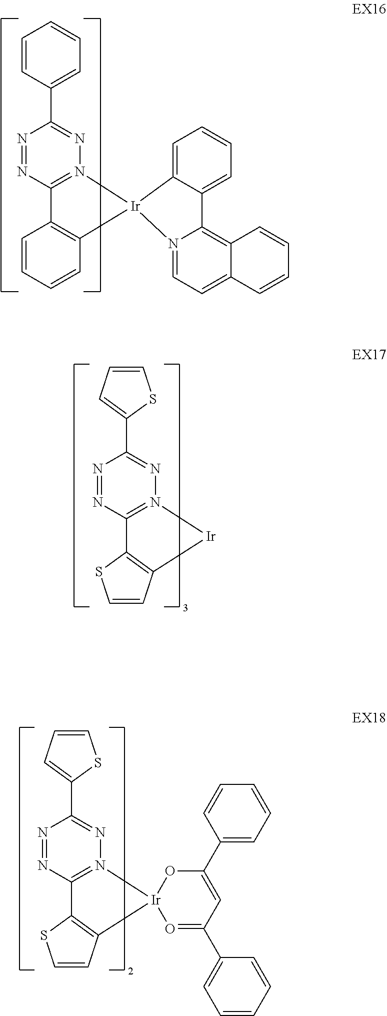

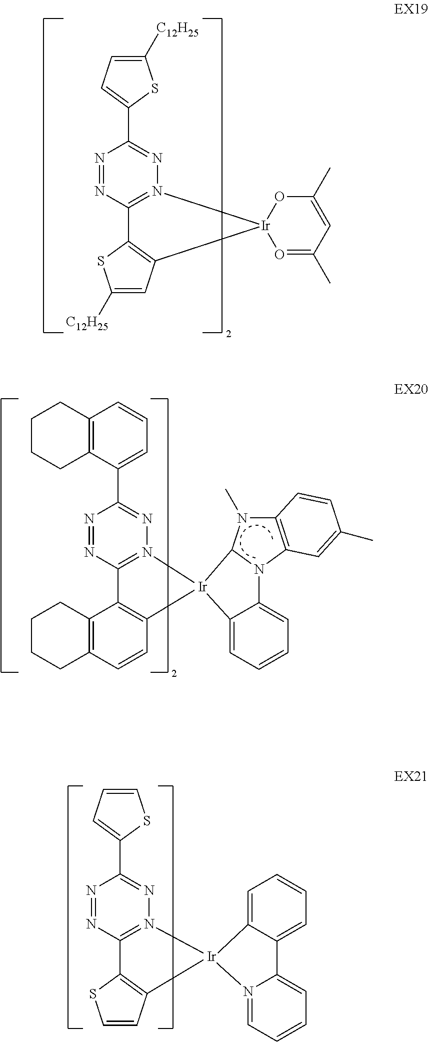

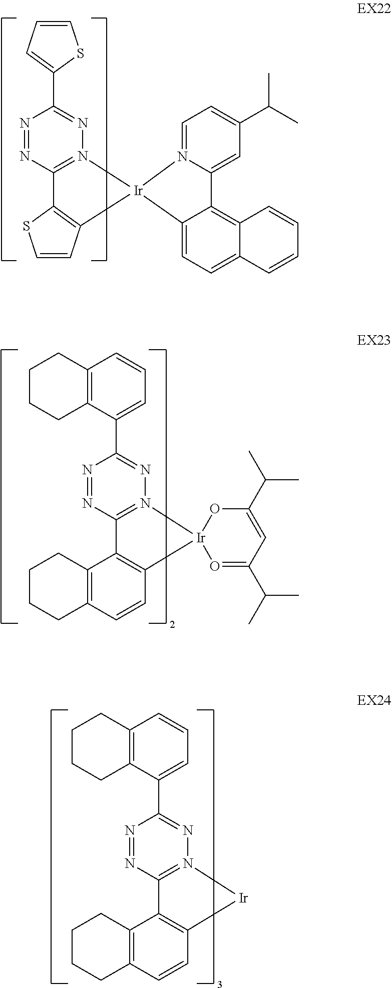

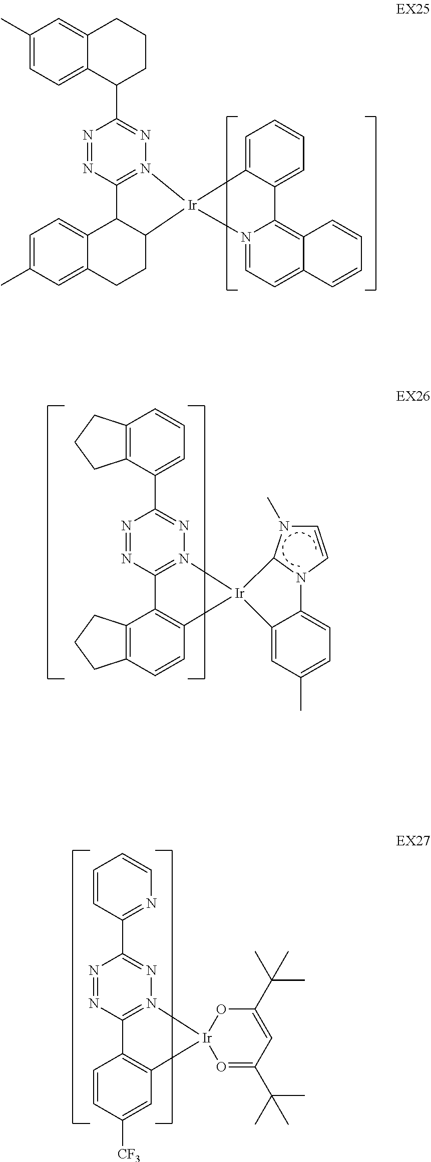

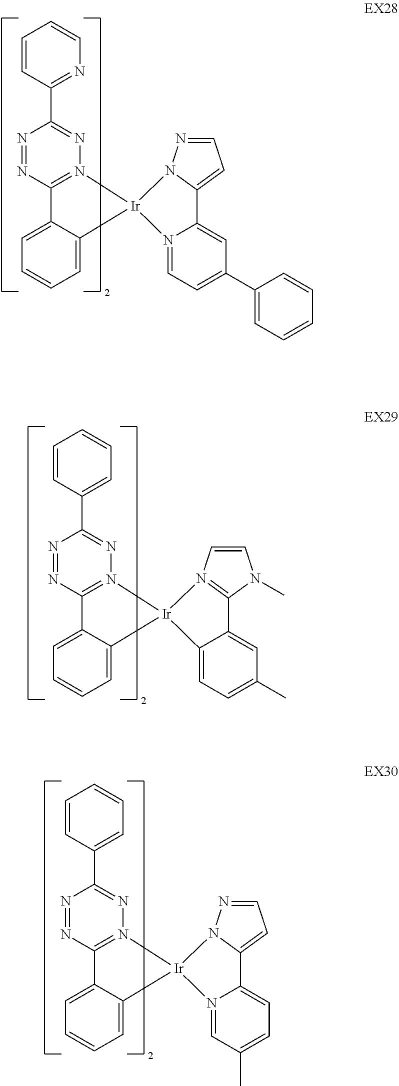

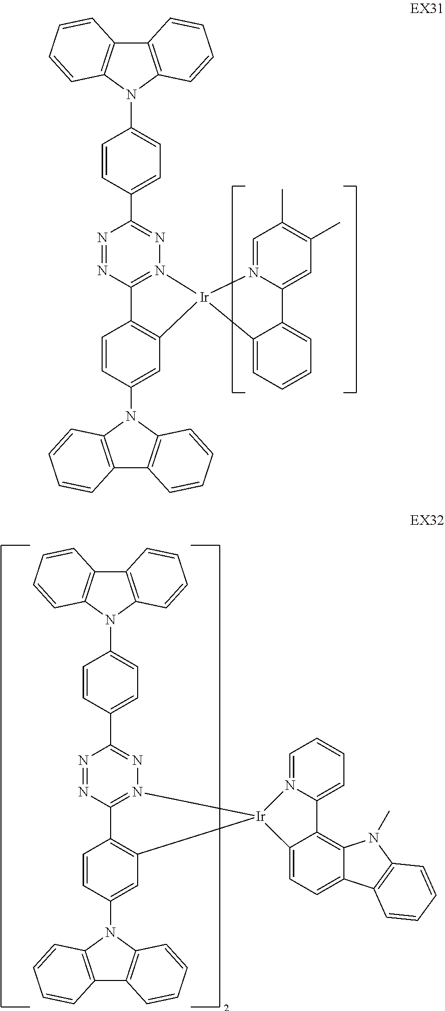

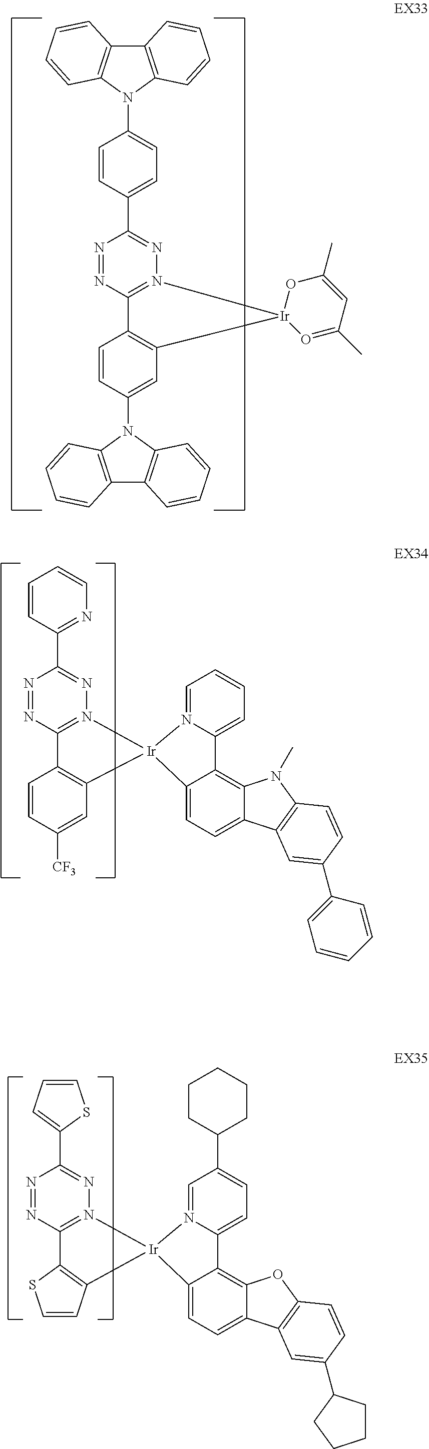

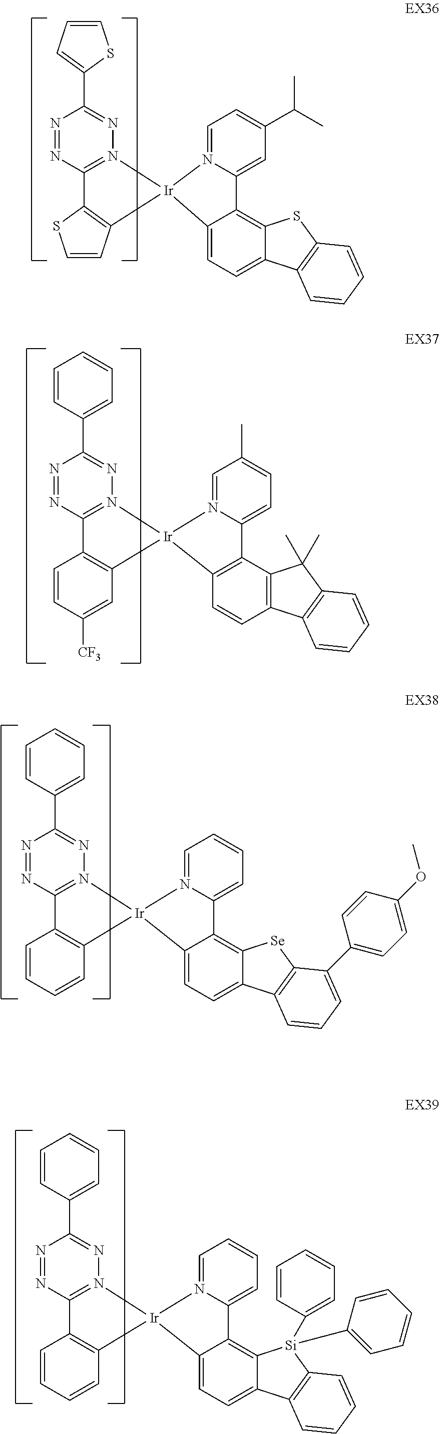

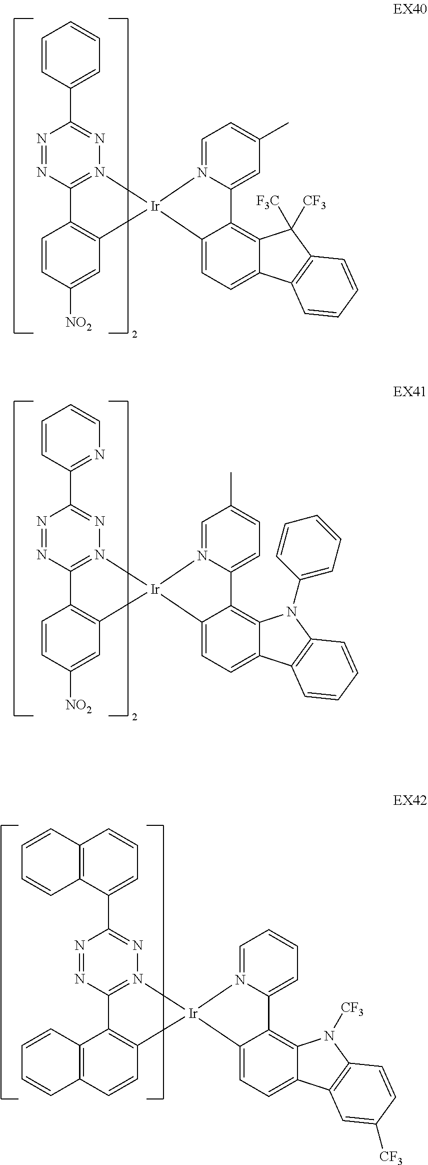

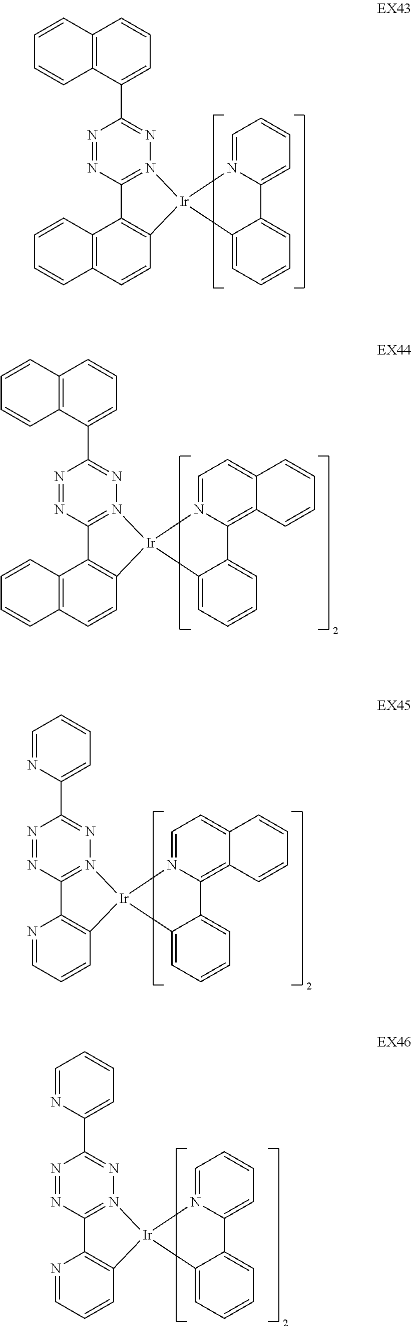

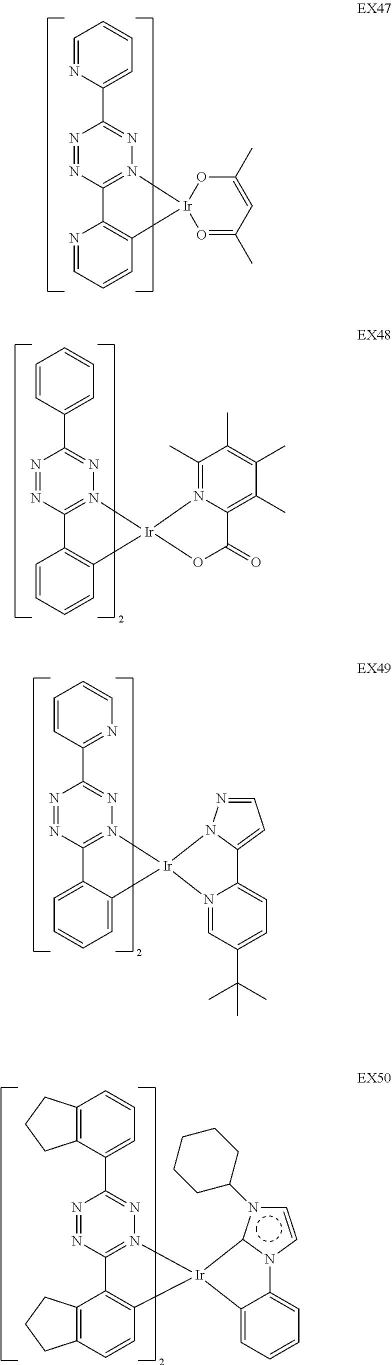

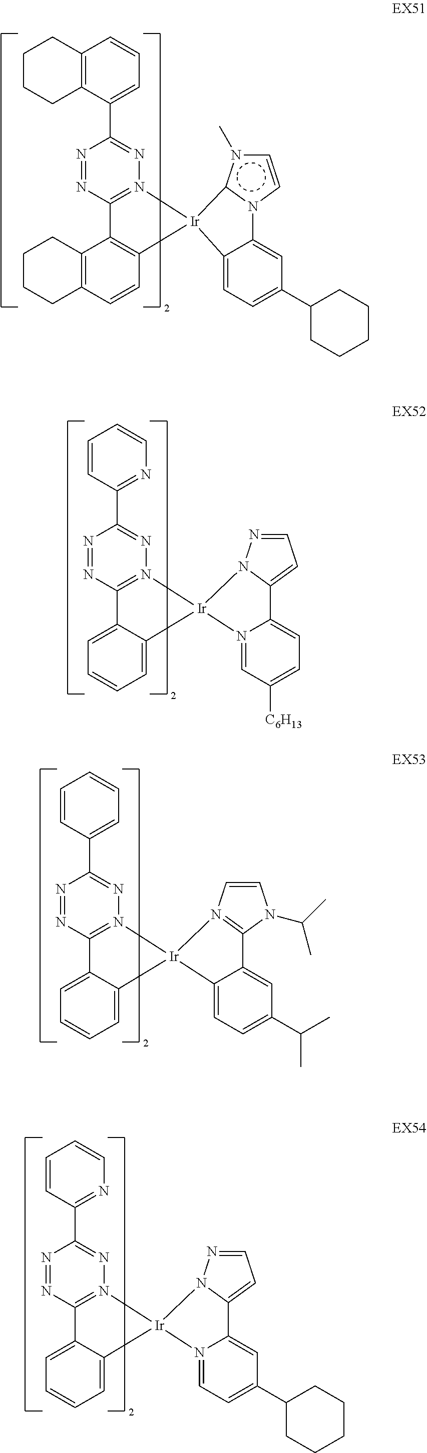

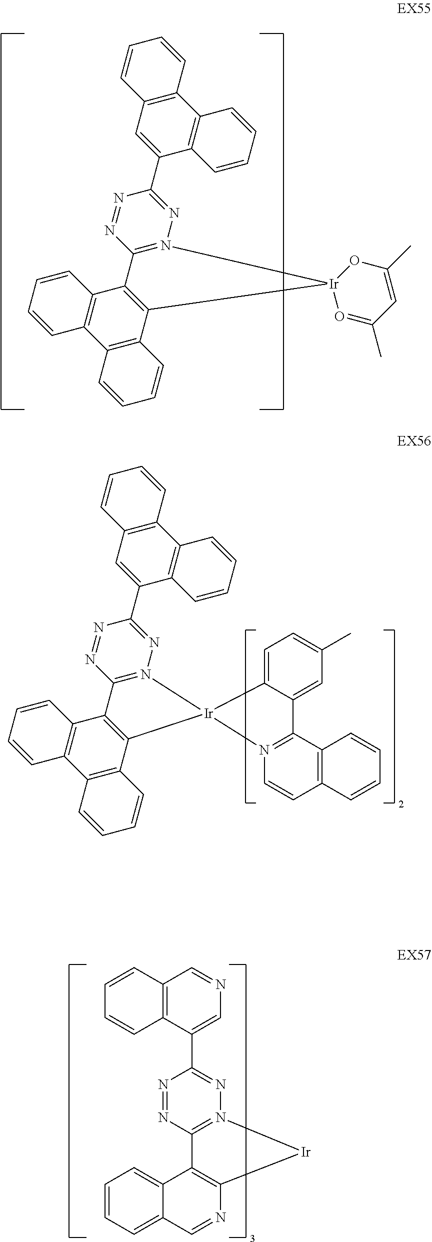

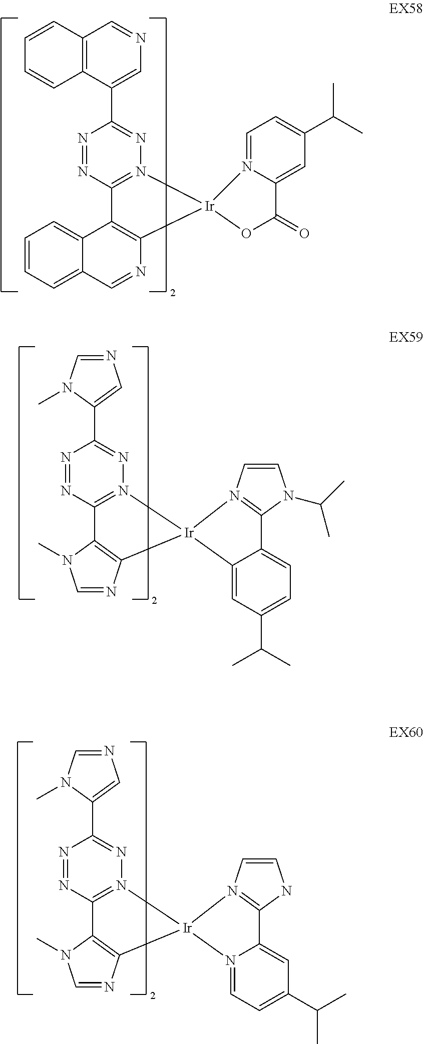

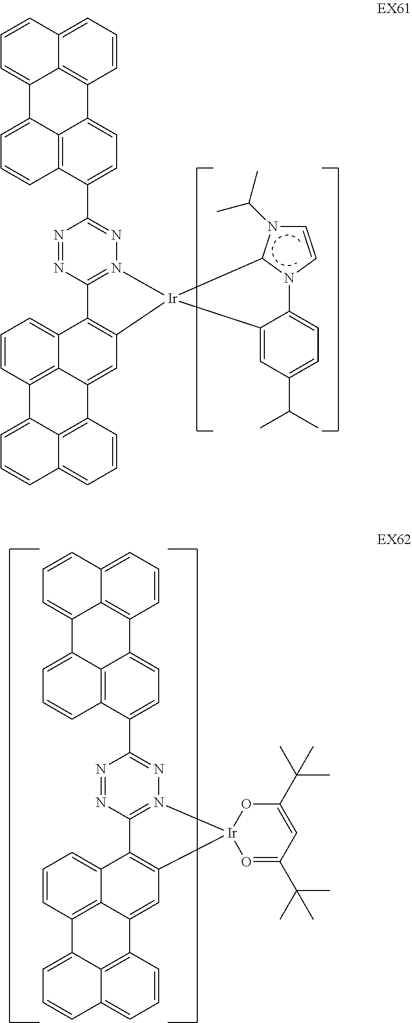

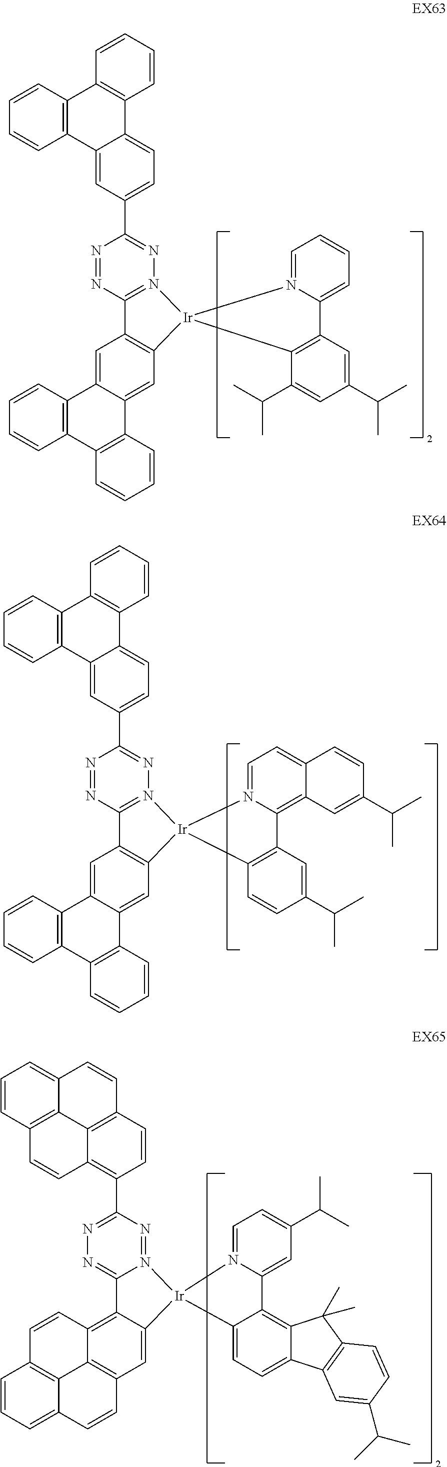

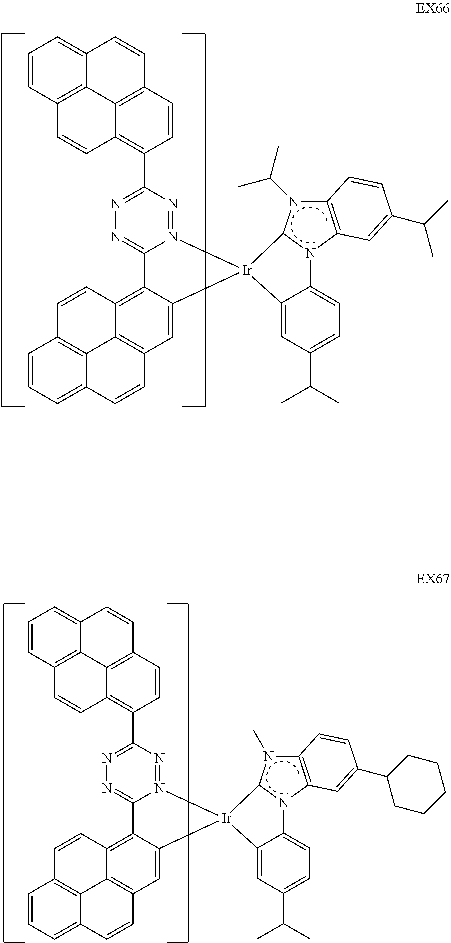

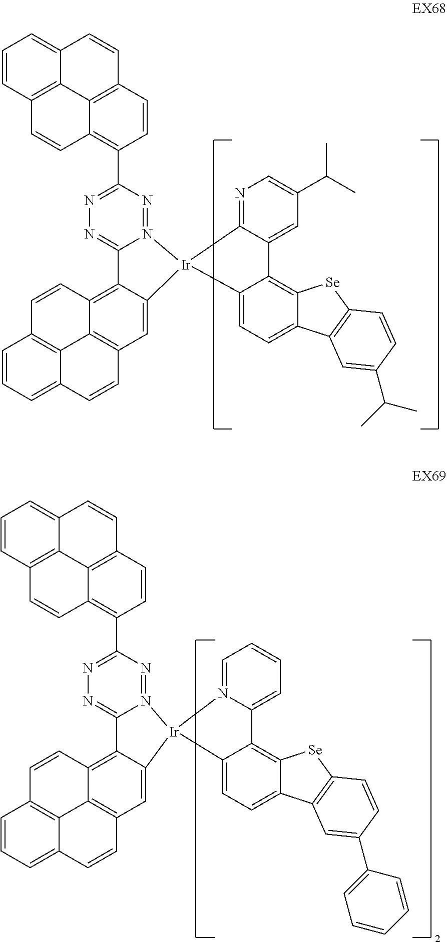

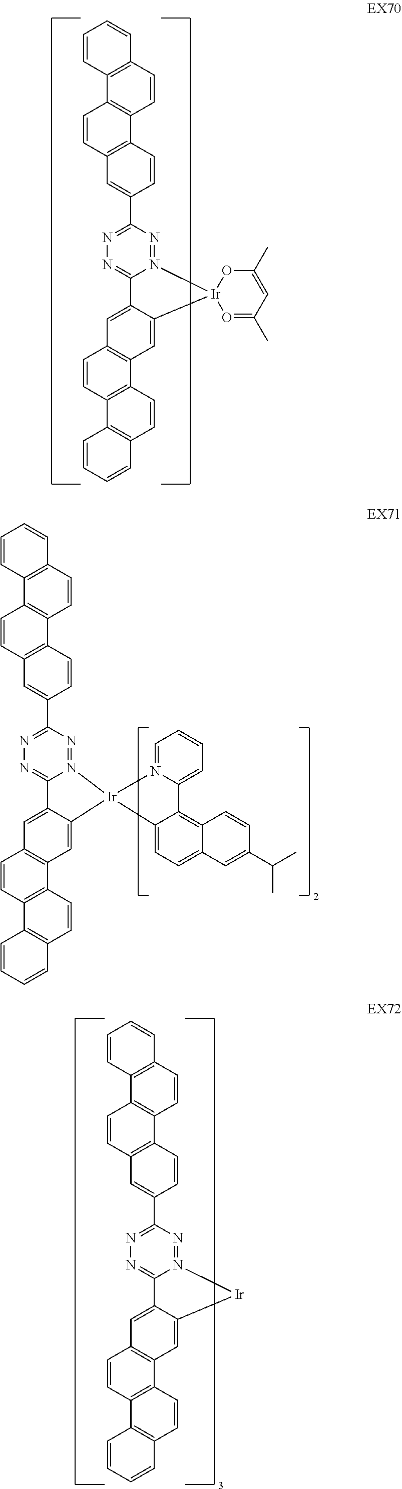

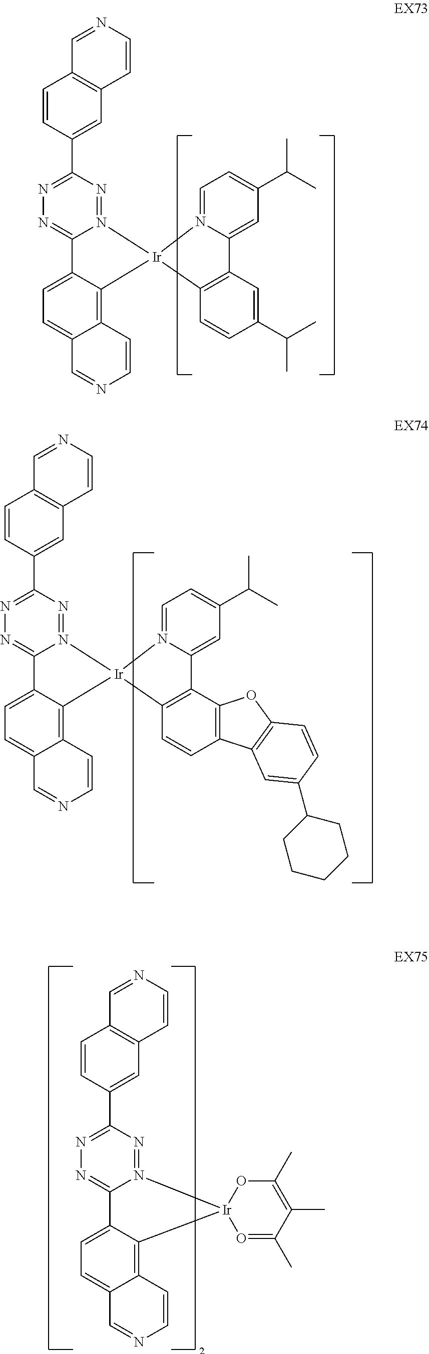

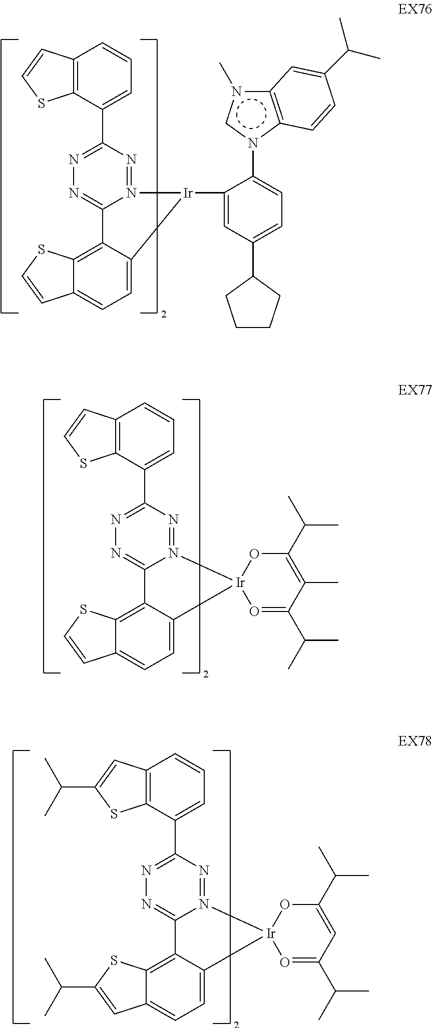

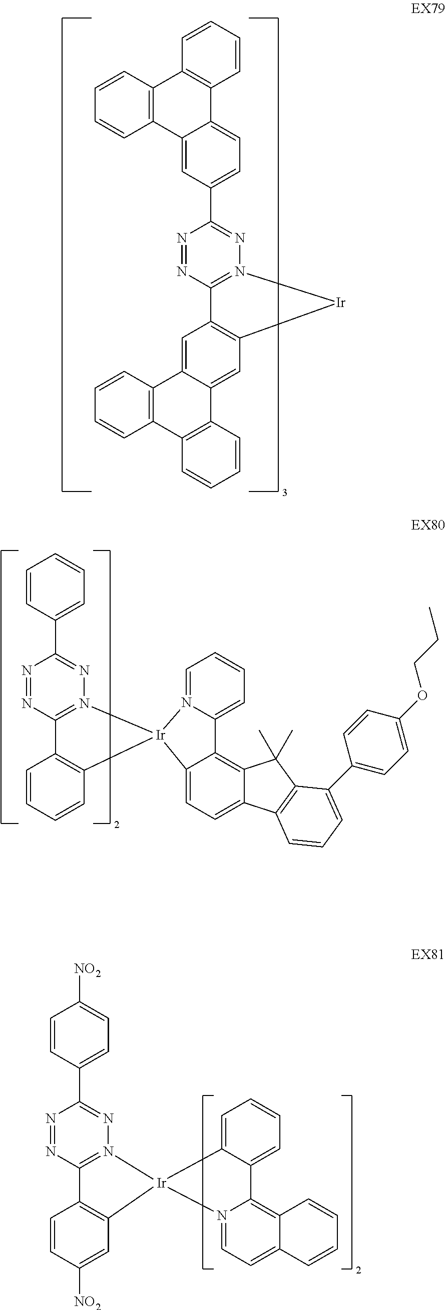

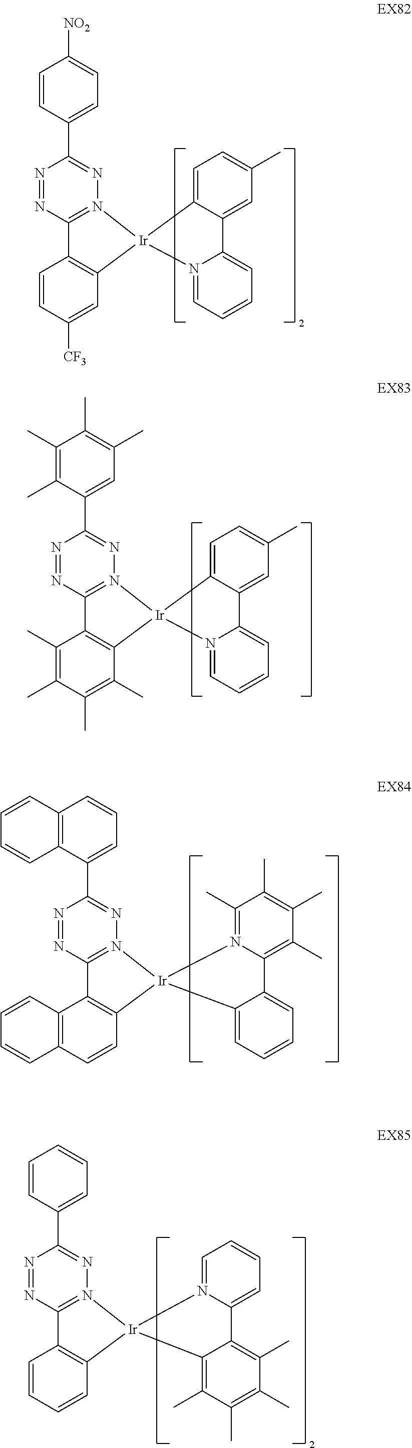

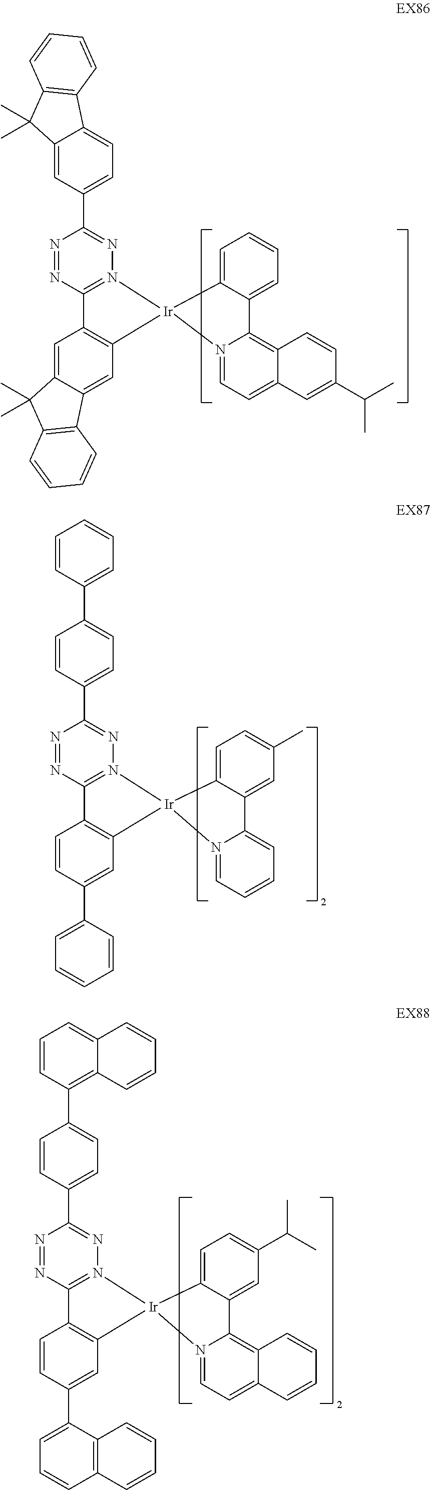

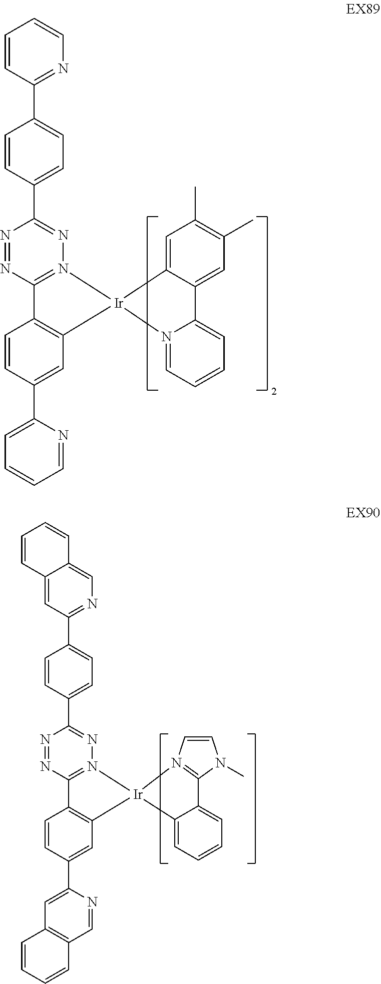

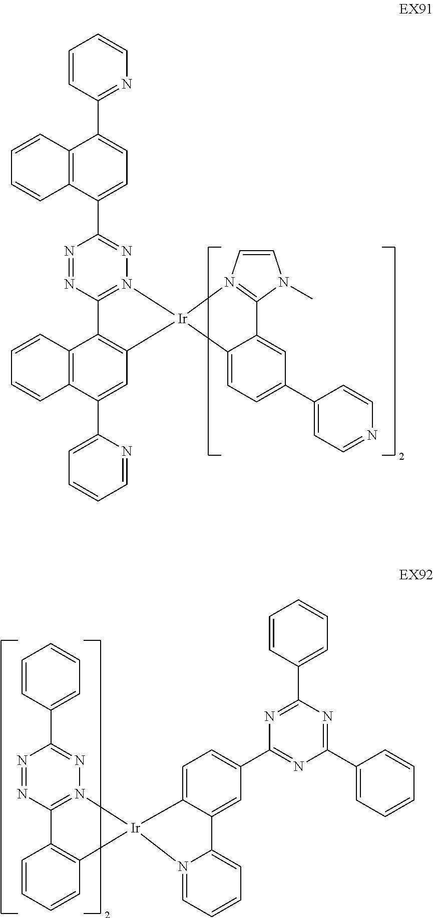

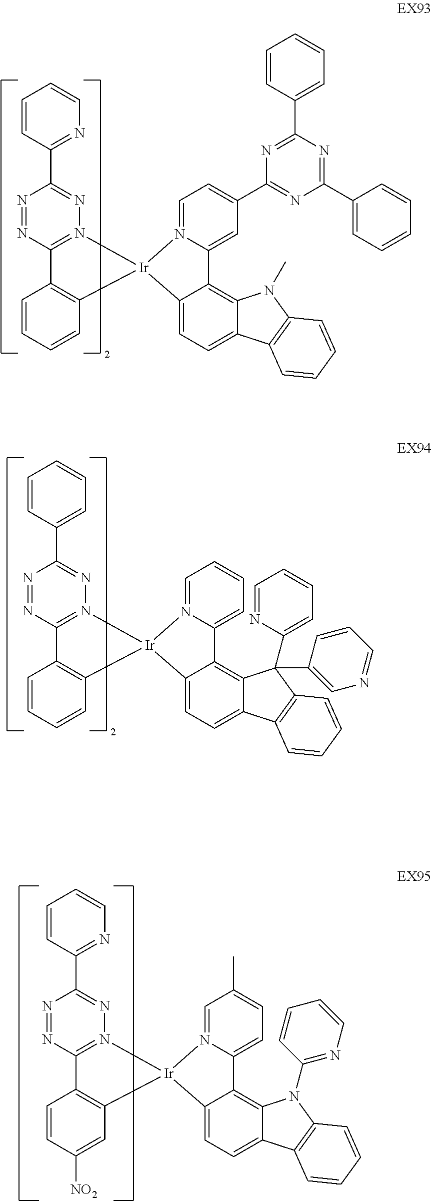

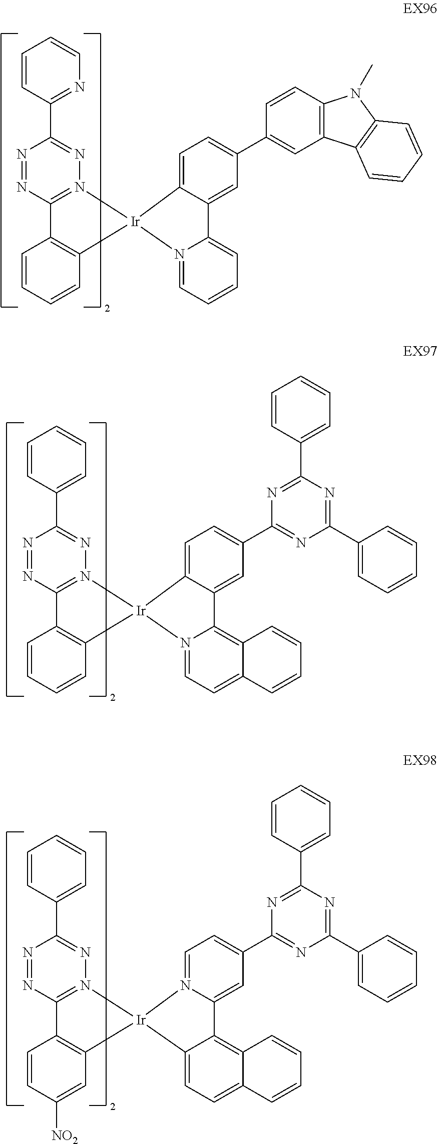

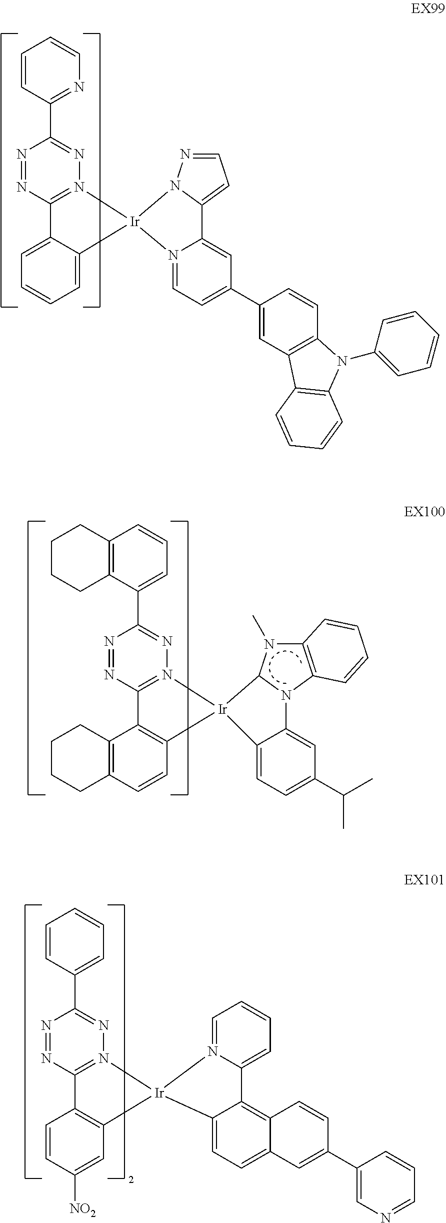

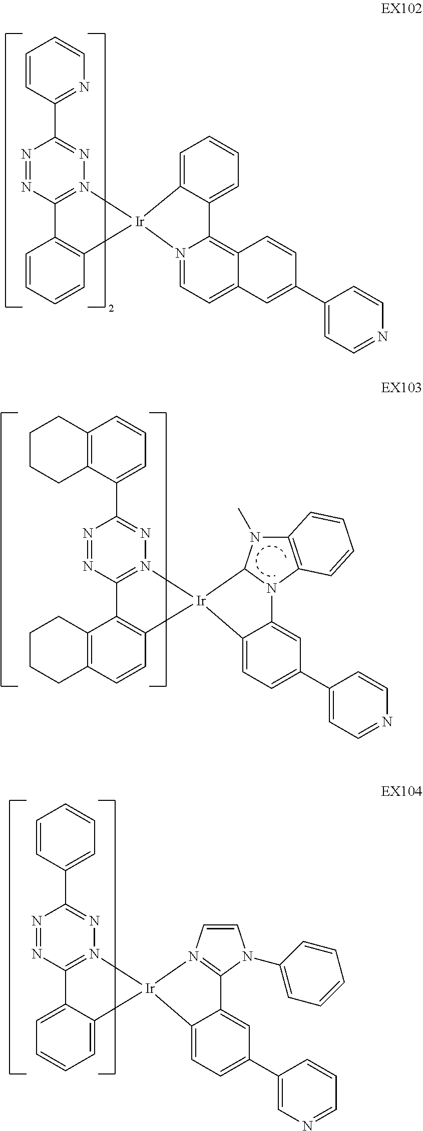

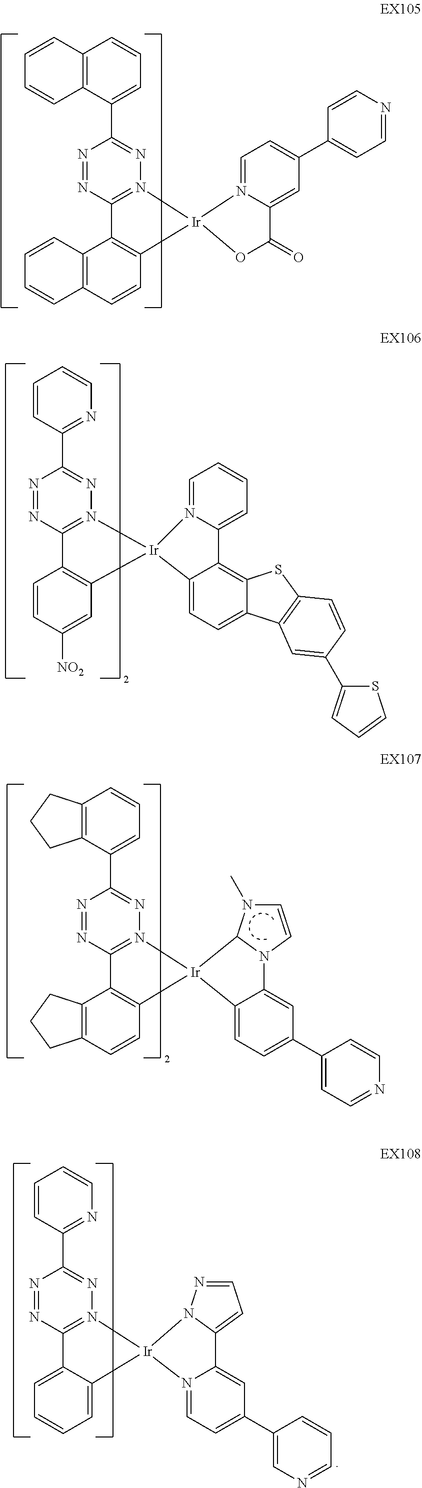

In another embodiment of the present invention, an organic electroluminescence device is disclosed. The organic electroluminescence device comprises a pair of electrodes composed of a cathode and an anode, and a light emitting layer between the pair of electrodes. The light emitting layer comprises the iridium complex of formula (1). In particular, the iridium complex of formula (1) is used as a phosphorescent dopant material.

In some embodiments, the light emitting layer emits red or yellow phosphorescence. In yet another embodiment of the present invention, the organic electroluminescent device is a lighting panel. In a further embodiment of the present invention, the organic electroluminescent device is a backlight panel.

Detailed preparation of the iridium complex of the present invention will be clarified by exemplary embodiments below, but the present invention is not limited thereto. EXAMPLES 1 to 15 show the preparation of the iridium complex of the present invention, and EXAMPLE 16 shows the fabrication and the testing report of the organic EL devices.

### Example 1

### Synthesis of EX1

### Synthesis of 3,6-diphenyl-1,2,4,5-tetrazine

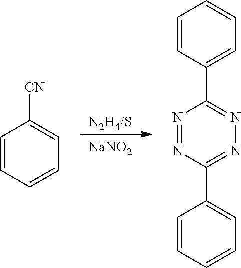

A mixture of 20.6 g (200 mmol) of benzonitrile, 10 g (312 mmol) of hydrazine monohydrate, 4 g (124.7 mmol) of sulfur, and 150 ml of ethanol was degassed and placed under nitrogen, and then heated to reflux for 18 hrs. After the reaction finished, the mixture was allowed to cool to room temperature. Subsequently, the solvent was removed under reduced pressure to afford a yellowish solid. The crude mixture was dissolved in acetic acid (112 mL) and water (38 mL). To the mixture, 9.0 g (134.1 mmol) of sodium nitrite was added slowly at room temperature and then stirred at room temperature for 2 hrs. The deep purple solid was filtered using a glass frit and recrystallized from 250 mL of CH₂Cl₂/hexane (1:10), yielding 4.5 g of 3,6-diphenyl-1,2,4,5-tetrazine as deep purple solid (19%), ¹H NMR (CDCl₃, 400 MHz): chemical shift (ppm) 8.65-8.63 (m, 4H), 7.63-7.48 (m, 6H).

### Synthesis of Intermediate A

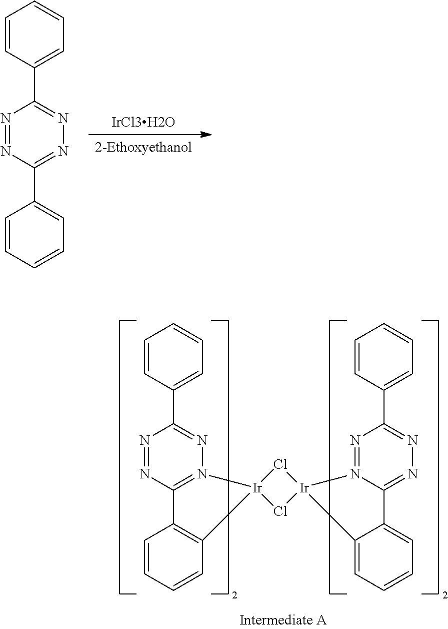

A mixture of 2 g (8.54 mmol) of 3,6-diphenyl-1,2,4,5-tetrazine, 1.4 g (3.88 mmol) of Iridium(III) chloride hydrate, 30 ml of 2-Ethoxyethanol and 10 ml of water was degassed and placed under nitrogen, and then heated at 120° C. overnight. After the reaction finished, the mixture was allowed to cool to room temperature. The precipitated product was filtered off with suction and washed with water. Afterwards, 100 ml of water was added and stirred for 1 hr, and then the precipitated product was filtered off with suction. Subsequently, 50 ml of EtOH was added and stirred for 1 hr, and then the precipitated product was filtered off with suction, yielding 1.1 g of Intermediate A as brown solid (40%)

### Synthesis of EX1

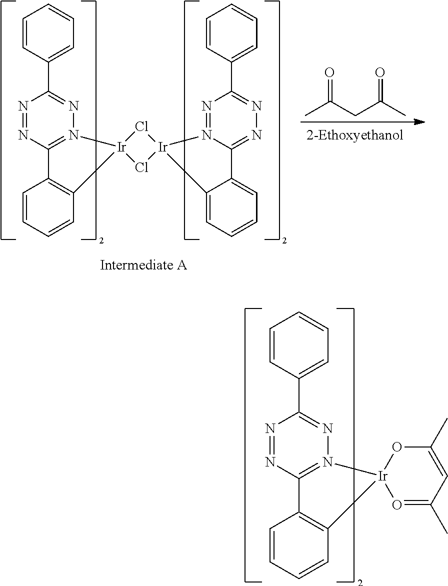

A mixture of 1.1 g (1.2 mmol) of Intermediate A, 1.2 g (12.0 mmol) of Acetylacetone, 1.6 g (12.0 mmol) of Sodium carbonate, and 9 ml of 2-Ethoxyethanol was degassed and placed under nitrogen, and then heated at 120° C. overnight. After the reaction finished, the mixture was allowed to cool to room temperature. The precipitated product was filtered off with suction and washed with water. Afterwards, 100 ml of water was added and stirred for 1 hr, and then the precipitated product was filtered off with suction. Subsequently, 50 ml of EtOH was added and stirred for 1 hr, and then the precipitated product was filtered off with suction, yielding 0.82 g of EX1 as red solid (45%). ¹H NMR (CDCl₃, 400 MHz): chemical shift (ppm) 8.55-8.43 (m, 6H), 7.73-7.41 (m, 12H), 5.25 (s, 1H), 1.83 (s, 6H) ppm.

### Example 2

### Synthesis of EX3

### Synthesis of EX3

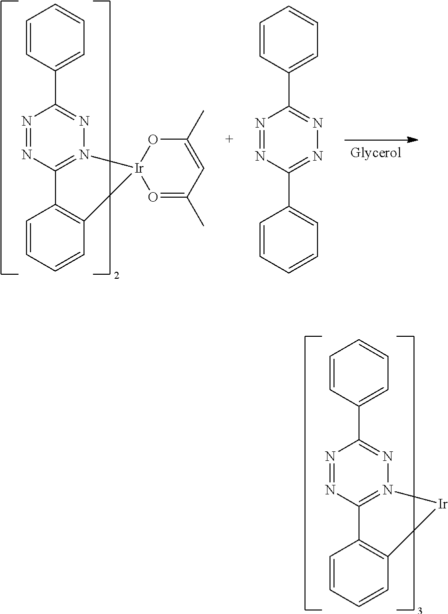

A mixture of 1.6 g (2.1 mmol) of EX1, 1.5 g (6.3 mmol) of 3,6-diphenyl-1,2,4,5-tetrazine, and 130 ml of glycerol was degassed and placed under nitrogen, and then heated at 200° C. overnight. After the reaction finished, the mixture was allowed to cool to room temperature. After the reaction finished, the mixture was allowed to cool to room temperature. Afterwards, 500 ml of water was added and stirred for 1 hr, and then the precipitated product was filtered off with suction. The crude solid was purified by column chromatography on silica, yielding 1.0 g of EX3 as brown solid (53%), ¹H NMR (CDCl₃, 400 MHz): chemical shift (ppm) 8.65-8.43 (m, 3H), 7.61-7.41 (m, 6H).

### Example 3

### Synthesis of EX16

### Synthesis of Intermediate B

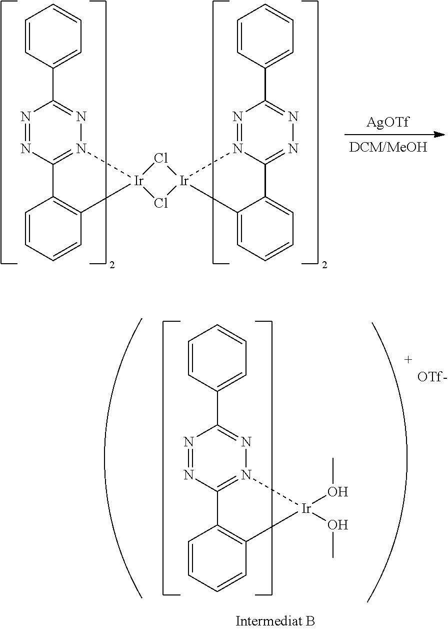

A mixture of 3.3 g (2.4 mmol) of Intermediate A, 1.4 g (5.5 mmol) of silver triflate, 130 ml of dichloromethane and 7 ml of methanol was placed under nitrogen, and then stirred overnight. After the reaction finished, the silver chloride was filtered off and the solvent was evaporated to obtain 4.0 g of iridium triflate precursor, which was used directly in the next step without purification.

### Synthesis of EX16

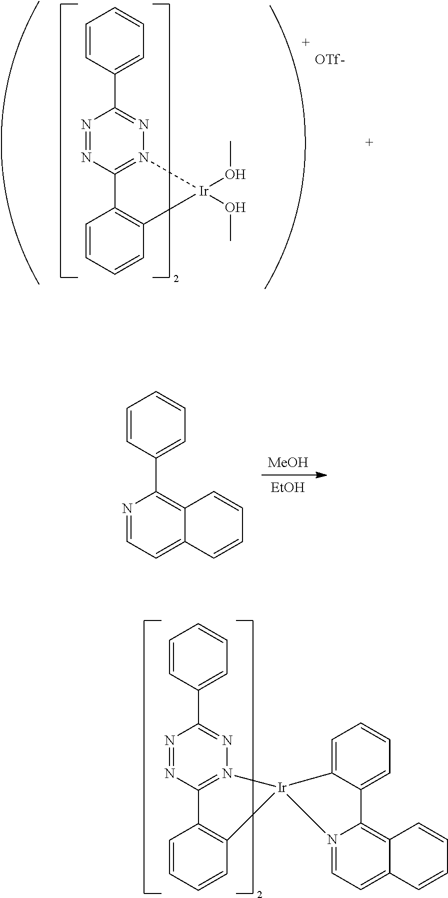

A mixture of 4.0 g (4.6 mmol) of Intermediate B, 2.8 g (13.8 mmol) of 1-Phenylisoquinoline, 90 ml of EtOH and 90 ml of MeOH was placed under nitrogen, and then heated to reflux overnight. After the reaction finished, the mixture was allowed to cool to room temperature. The orange-red precipitate formed was filtered under vacuum, washed with ethanol and hexane, and then purified by vacuum sublimation to give 2.1 g (54%) of orange-red product EX16. MS (m/z, EI⁺): 863.22

### Example 4

### Synthesis of EX18

### Synthesis of 3,6-di(thiophen-2-yl)-1,2,4,5-tetrazine

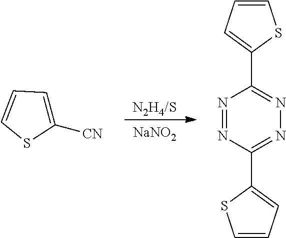

A mixture of 21.8 g (200 mmol) of 2-Thiophenecarbonitrile, 10 g (312 mmol) of hydrazine monohydrate, 4 g (124.7 mmol) of Sulfur, and 150 ml of ethanol was degassed and placed under nitrogen, and then heated to reflux for 18 hrs. After the reaction finished, the mixture was allowed to cool to room temperature. Subsequently, the solvent was removed under reduced pressure to afford a yellowish solid. The crude mixture was then dissolved in acetic acid (112 mL) and water (38 mL). To the mixture, 9.0 g (134.1 mmol) of Sodium nitrite was added slowly at room temperature and then stirred at room temperature for 2 hrs. The deep purple solid was filtered using a glass frit and recrystallized from 250 mL of CH₂Cl₂/hexane 1:10, yielding 5.2 g of 3,6-di(thiophen-2-yl)-1,2,4,5-tetrazine, as deep purple solid (22%), ¹H NMR (CDCl₃, 400 MHz): chemical shift (ppm) 8.01-7.81 (m, 4H), 7.21-7.15 (m, 2H).

### Synthesis of Intermediate C

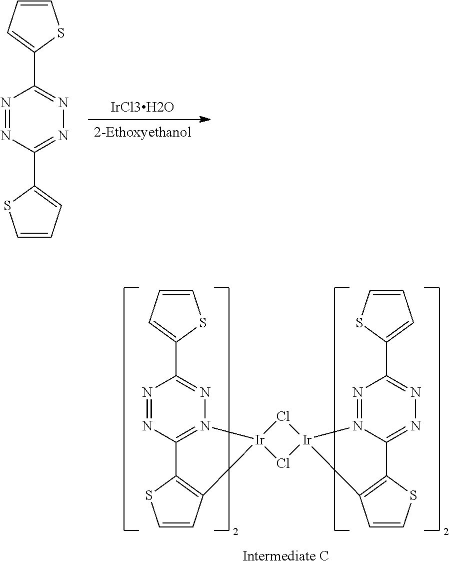

A mixture of 2 g (8.13 mmol) of 3,6-di(thiophen-2-yl)-1,2,4,5-tetrazine, 1.3 g (3.70 mmol) of Iridium(III) chloride hydrate, 30 ml of 2-Ethoxyethanol and 10 ml water was degassed and placed under nitrogen, and then heated at 120° C. overnight. After the reaction finished, the mixture was allowed to cool to room temperature. The precipitated product was filtered off with suction and washed with water. Afterwards, 100 ml of water was added and stirred for 1 hr, and then the precipitated product was filtered off with suction. Subsequently, 50 ml of EtOH was added and stirred for 1 hr, and then the precipitated product was filtered off with suction, yielding 1.28 g of Intermediate C as brown solid (48%)

### Synthesis of EX18

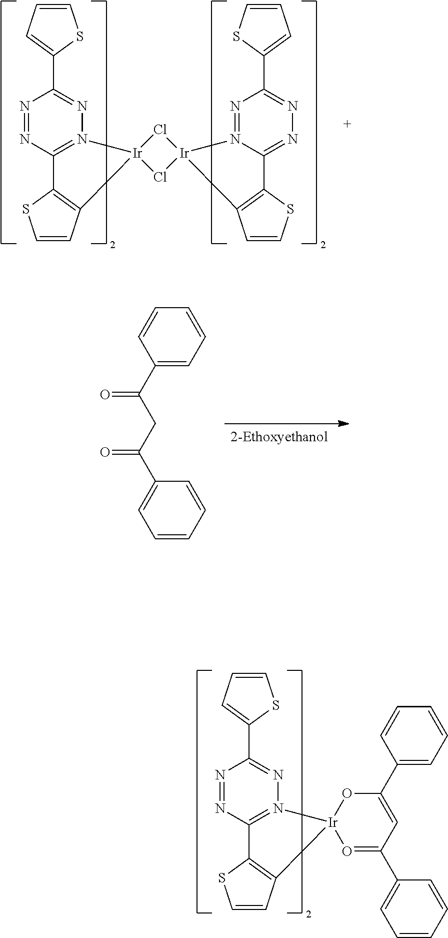

A mixture of 1.28 g (0.89 mmol) of Intermediate C, 2.0 g (8.9 mmol) of 1,3-Diphenylpropane-1,3-dione, 1.9 g (17.8 mmol) of sodium carbonate, and 40 ml of 2-ethoxyethanol was degassed and placed under nitrogen, and then heated at 80° C. while stirring for 16 h. After the reaction finished, the mixture was allowed to cool to room temperature. The precipitated product was filtered with suction and then washed with water. Afterwards, 100 ml of water was added and stirred for 1 hr, and then the precipitated product was filtered with suction. Subsequently, 10 ml of EtOH was added and stirred for 1 hr, and then the precipitated product was filtered with suction to give 0.92 g (57%) of red product EX18. MS (m/z, EI⁺): 906.04

### Example 5

### Synthesis of EX21

### Synthesis of Intermediate D

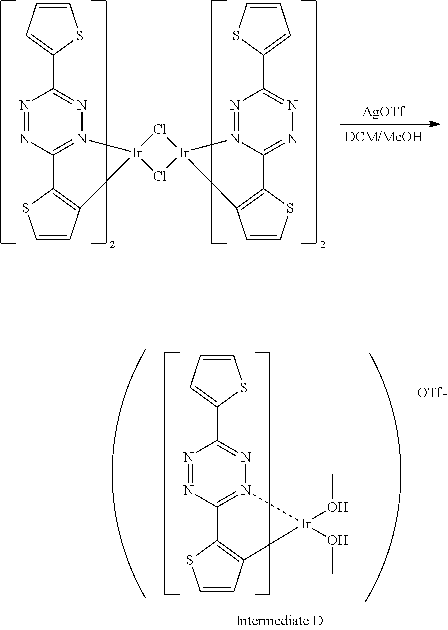

A mixture of 4.1 g (2.8 mmol) of Intermediate C, 1.6 g (6.4 mmol) of silver triflate, 140 ml of dichloromethane and 8 ml of methanol was placed under nitrogen, and then stirred overnight. After the reaction finished, the silver chloride was filtered off and the solvent was evaporated to obtain 4.5 g of iridium triflate precursor, which was used directly in the next step without purification.

### Synthesis of EX21

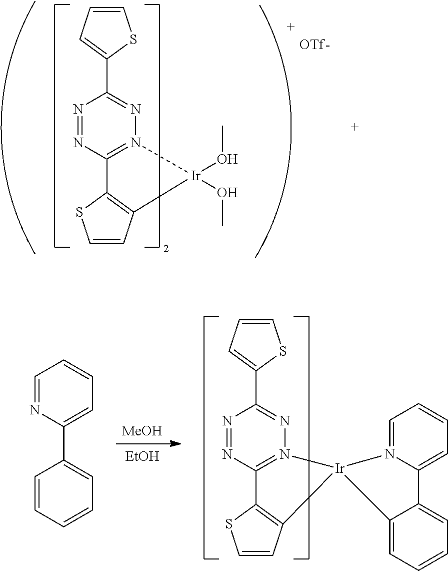

A mixture of 4.5 g (5.0 mmol) of Intermediate D, 1.4 g (9.3 mmol) of 2-Phenylpyridine, 70 ml of EtOH and 70 ml of MeOH was placed under nitrogen, and then heated to reflux overnight. After the reaction finished, the mixture was allowed to cool to room temperature. The yellow precipitate formed was filtered under vacuum, washed with ethanol and hexane, and then purified by vacuum sublimation to give 2.6 g (62%) of yellow product EX21. MS (m/z, EI⁺): 837.03

### Example 6

### Synthesis of EX22

### Synthesis of EX22

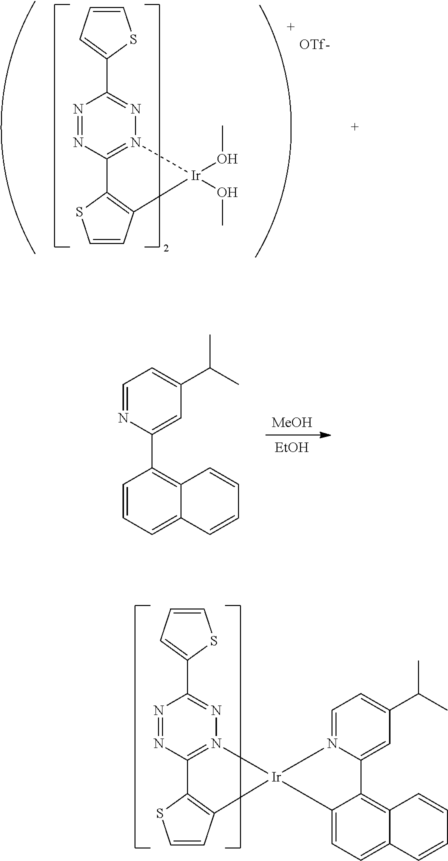

A mixture of 5.0 g (5.6 mmol) of Intermediate D, 2.6 g (10.4 mmol) of 4-Isopropyl-2-(naphthalen-1-yl)pyridine, 80 ml of EtOH and 80 ml of MeOH was placed under nitrogen, and then heated to reflux overnight. After the reaction finished, the mixture was allowed to cool to room temperature. The yellow precipitate formed was filtered under vacuum, washed with ethanol and hexane, and then purified by vacuum sublimation to give 3.0 g (59%) of yellow product EX22. MS (m/z, EI⁺): 930.09

### Example 7

### Synthesis of EX27

### Synthesis of 3-(Pyridin-2-yl)-6-(4-(trifluoromethyl)phenyl)-1,2,4,5-tetrazine

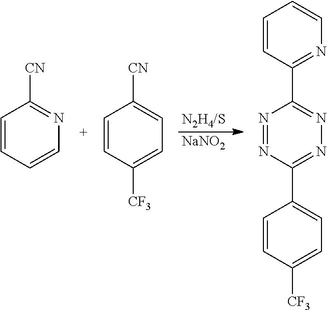

A mixture of 10.4 g (100 mmol) of 2-Pyridinecarbonitrile, 17.1 g (100 mmol) of 4-(Trifluoromethyl)benzonitrile, 16.0 g (500 mmol) of hydrazine monohydrate, 6.4 g (200 mmol) of Sulfur, and 150 ml of ethanol was degassed and placed under nitrogen, and then heated to reflux for 18 hrs. After the reaction finished, the mixture was allowed to cool to room temperature. Subsequently, the solvent was removed under reduced pressure to afford a yellowish solid. The crude mixture was dissolved in acetic acid (112 mL) and water (38 mL). To the mixture, 9 g (134.1 mmol) of Sodium nitrite was added slowly at room temperature and then stirred at room temperature for 2 hrs. The deep purple solid was filtered using a glass frit and recrystallized from 250 mL of CH₂Cl₂/hexane 1:10, yielding 14.2 g of 3-(Pyridin-2-yl)-6-(4-(trifluoro-methyl)phenyl)-1,2,4,5-tetrazine as deep purple solid (47%), ¹H NMR (CDCl₃, 400 MHz): chemical shift (ppm) 9.03 (d, 1H), 8.91 (d, 2H), 8.69 (d, 1H), 7.99-7.89 (m, 3H), 7.59 (t, 1H).

### Synthesis of Intermediate E

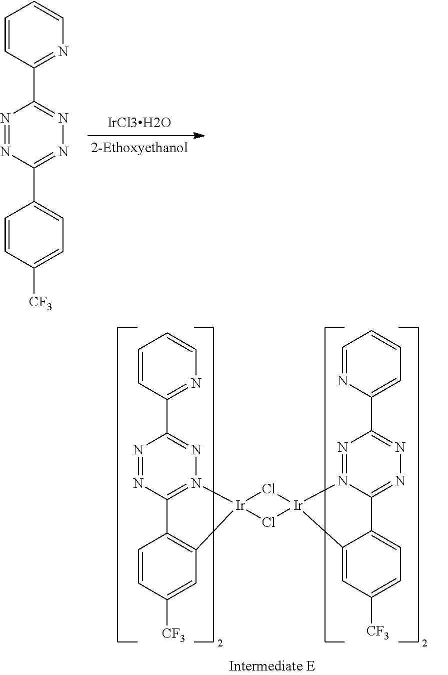

A mixture of 4.0 g (13.2 mmol) of 3-(Pyridin-2-yl)-6-(4-(trifluoro-methyl)phenyl)-1,2,4,5-tetrazine, 2.2 g (6.0 mmol) of Iridium(III) chloride hydrate, 60 ml of 2-Ethoxyethanol and 20 ml water was degassed and placed under nitrogen, and then heated at 120° C. overnight. After the reaction finished, the mixture was allowed to cool to room temperature. The precipitated product was filtered off with suction and washed with water. Afterwards, 100 ml of water was added and stirred for 1 hr, and then the precipitated product was filtered off with suction. Subsequently, 50 ml of EtOH was added and stirred for 1 hr, and then the precipitated product was filtered off with suction, yielding 2.8 g of Intermediate E as brown solid (57%)

### Synthesis of EX27

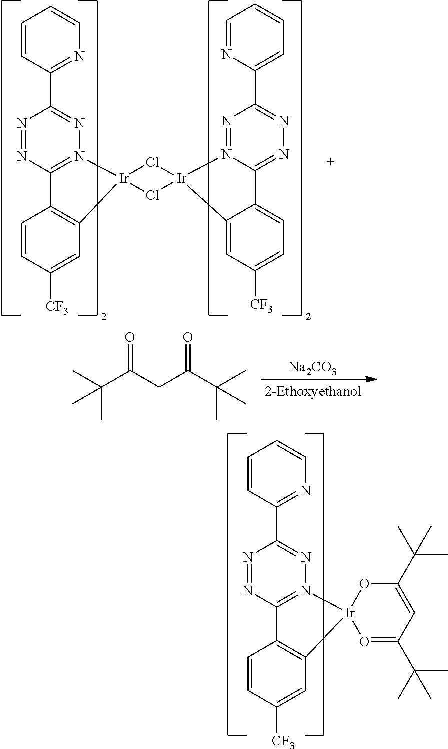

A mixture of 2.8 g (1.68 mmol) of Intermediate E, 3.1 g (16.8 mmol) of 2,2,6,6-tetramethylheptane-3,5-dione, 3.6 g (33.6 mmol) of sodium carbonate, and 50 ml of 2-ethoxyethanol was degassed and placed under nitrogen, and then heated at 80° C. while stirring for 16 h. After the reaction finished, the mixture was allowed to cool to room temperature. The precipitated product was filtered with suction and then washed with water. Afterwards, 100 ml of water was added and stirred for 1 hr, and then the precipitated product was filtered with suction. Subsequently, 10 ml of EtOH was added and stirred for 1 hr, and then the precipitated product was filtered with suction to give 1.7 g (53%) of red product EX27. MS (m/z, EI⁺): 981.24

### Example 8

### Synthesis of EX29

### Synthesis of EX29

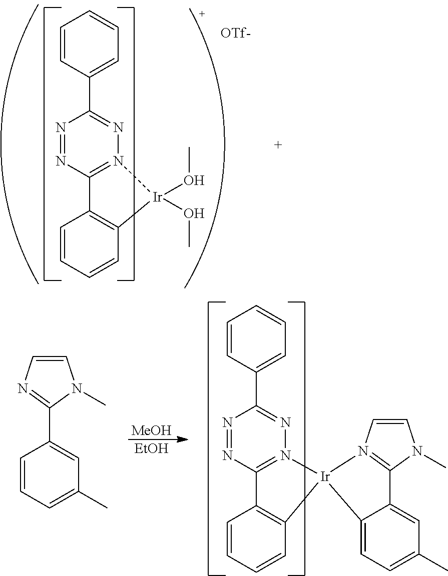

A mixture of 5.0 g (5.7 mmol) of Intermediate B, 2.9 g (17.1 mmol) of 1-Methyl-2-(3-methylphenyl)-1H-imidazole, 100 ml of EtOH and 100 ml of MeOH was placed under nitrogen, and then heated to reflux overnight. After the reaction finished, the mixture was allowed to cool to room temperature. The orange-red precipitate formed was filtered under vacuum, washed with ethanol and hexane, and then purified by vacuum sublimation to give 2.7 g (57%) of orange-red product EX29. MS (m/z, EI⁺): 831.23

### Example 9

### Synthesis of EX30

### Synthesis of EX30

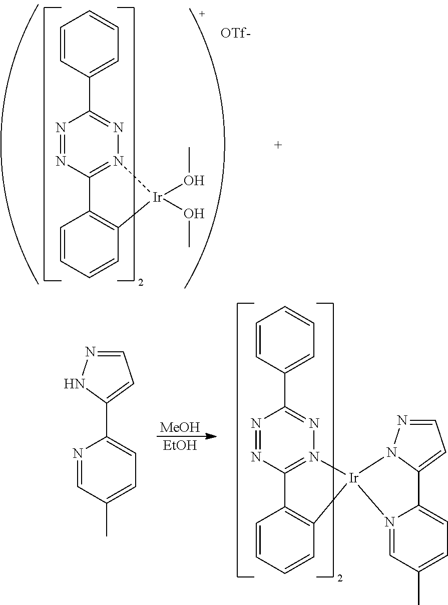

A mixture of 5.0 g (5.7 mmol) of Intermediate B, 2.7 g (17.1 mmol) of 5-methyl-2-(1H-pyrazol-5-yl)pyridine, 100 ml of EtOH and 100 ml of MeOH was placed under nitrogen, and then heated to reflux overnight. After the reaction finished, the mixture was allowed to cool to room temperature. The orange-red precipitate formed was filtered under vacuum, washed with ethanol and hexane, and then purified by vacuum sublimation to give 2.7 g (59%) of orange-red product EX30. MS (m/z, EI+): 816.20

### Example 10

### Synthesis of EX34

### Synthesis of Intermediate F

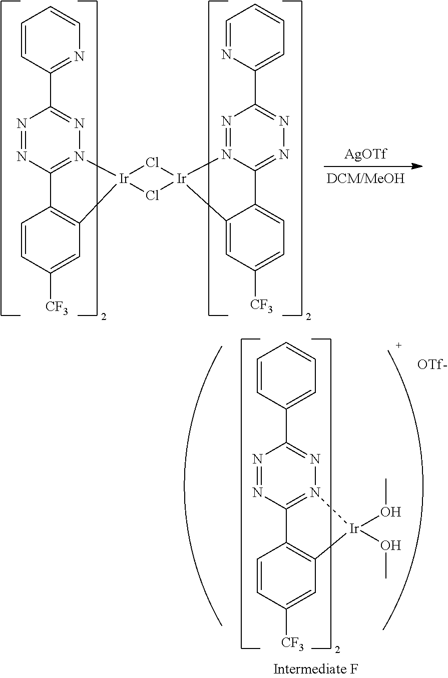

A mixture of 4.1 g (2.5 mmol) of Intermediate E, 1.5 g (5.7 mmol) of silver triflate, 140 ml of dichloromethane and 8 ml of methanol was placed under nitrogen, and then stirred overnight. After the reaction finished, the silver chloride was filtered off and the solvent was evaporated to obtain 4.9 g of iridium triflate precursor, which was used directly in the next step without purification.

### Synthesis of EX34

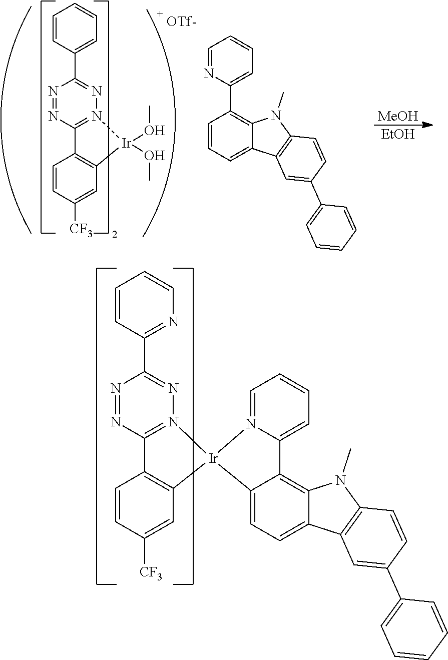

A mixture of 4.9 g (4.8 mmol) of Intermediate F, 4.8 g (14.4 mmol) of 9-Methyl-6-phenyl-1-(pyridin-2-yl)-9H-carbazole, 100 ml of EtOH and 100 ml of MeOH was placed under nitrogen, and then heated to reflux overnight. After the reaction finished, the mixture was allowed to cool to room temperature. The orange-red precipitate formed was filtered under vacuum, washed with ethanol and hexane, and then purified by vacuum sublimation to give 3.4 g (63%) of orange product EX34. MS (m/z, EI⁺): 1131.24

### Example 11

### Synthesis of EX35

### Synthesis of EX35

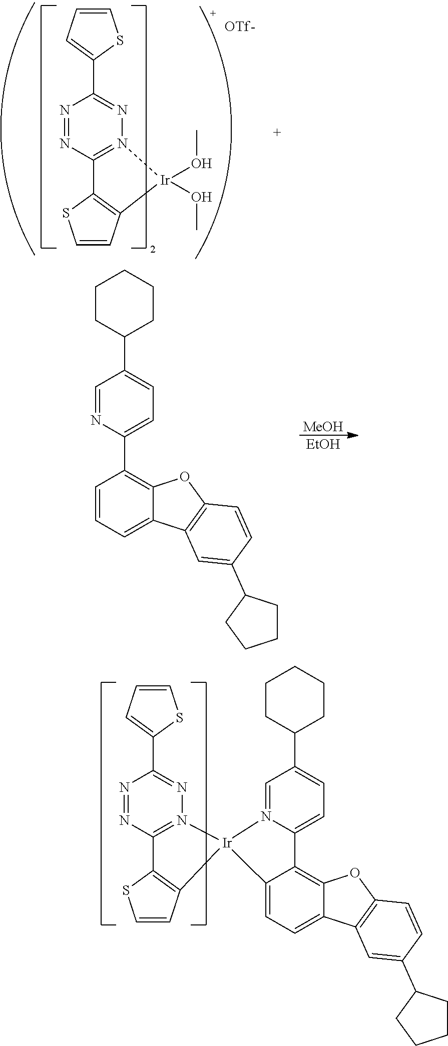

A mixture of 4.9 g (5.5 mmol) of Intermediate D, 4.0 g (10.2 mmol) of 5-Cyclohexyl-2-(8-cyclopentyldibenzo[b,d] furan-4-yl)pyridine, 70 ml of EtOH and 70 ml of MeOH was placed under nitrogen, and then heated to reflux overnight. After the reaction finished, the mixture was allowed to cool to room temperature. The yellow precipitate formed was filtered under vacuum, washed with ethanol and hexane, and then purified by vacuum sublimation to give 3.4 g (57%) of yellow-orange product EX35. MS (m/z, EI⁺): 1078.18

### Example 12

### Synthesis of EX36

### Synthesis of EX36

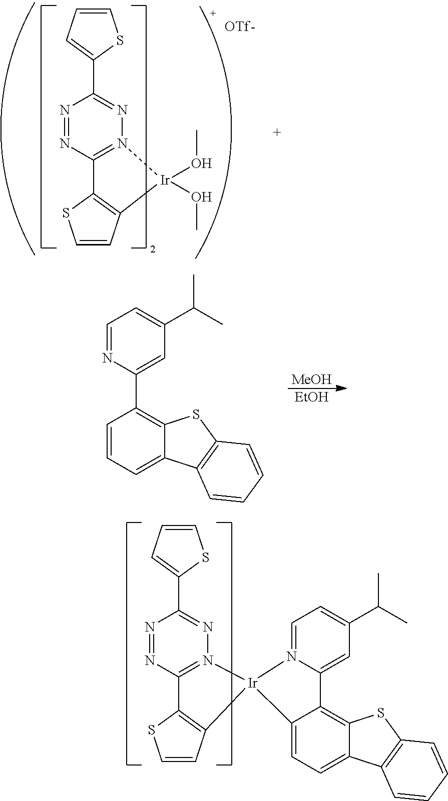

A mixture of 4.9 g (5.5 mmol) of Intermediate D, 3.1 g (10.2 mmol) of 2-(Dibenzo[b,d]thiophen-4-yl)-4-isopropylpyridine, 70 ml of EtOH and 70 ml of MeOH was placed under nitrogen, and then heated to reflux overnight. After the reaction finished, the mixture was allowed to cool to room temperature. The yellow precipitate formed was filtered under vacuum, washed with ethanol and hexane, and then purified by vacuum sublimation to give 3.0 g (55%) of yellow-orange product EX36. MS (m/z, EI⁺): 986.06

### Example 13

### Synthesis of EX48

### Synthesis of EX48

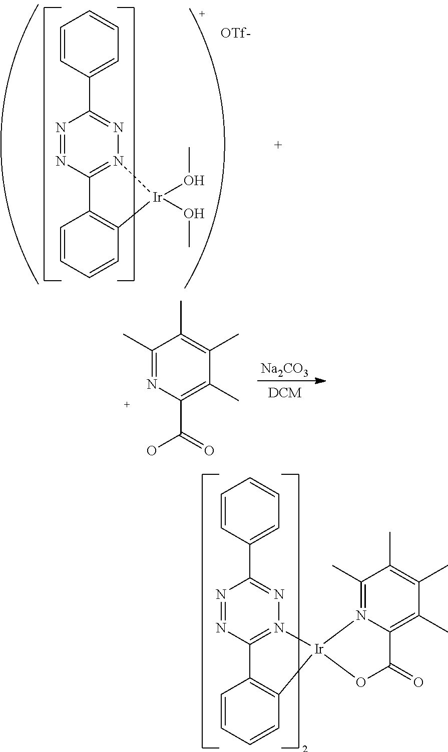

A mixture of 2.7 g (3.12 mole) of Intermediate B, 1.54 g (8.59 mmole) of 3,4,5,6-Tetramethylpicolinic acid, 1.32 g (12.49 mmole) of Sodium Carbonate, and 200 ml of dry dichloromethane was placed under nitrogen, and then heated to reflux for 48 hours. After the reaction finished, the mixture was allowed to cool to room temperature. The solution was extracted with dichloromethane and water. The organic layer was dried with anhydrous magnesium sulfate and then the solvent was evaporated under reduced pressure. The residue was purified by column chromatography on silica to give 1.7 g (65%) of yellow solid. MS (m/z, EI⁺): 838.22

### Example 14

### Synthesis of EX51

### Synthesis of 3,6-bis(5,6,7,8-tetrahydronaphthalen-1-yl)-1,2,4,5-tetrazine

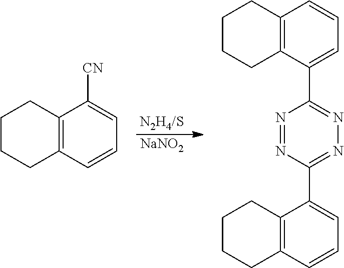

A mixture of 31.4 g (200 mmol) of 5,6,7,8-Tetrahydronaphthalene-1-carbonitrile, 10 g (312 mmol) of hydrazine monohydrate, 4 g (124.7 mmol) of Sulfur, and 150 ml of ethanol was degassed and placed under nitrogen, and then heated to reflux for 18 hrs. After the reaction finished, the mixture was allowed to cool to room temperature. Subsequently, the solvent was removed under reduced pressure to afford a yellowish solid. The crude mixture was dissolved in acetic acid (112 mL) and water (38 mL). To the mixture, 9.0 g (134.1 mmol) of Sodium nitrite was added slowly at room temperature and then stirred at room temperature for 2 hrs. The deep purple solid was filtered using a glass frit and recrystallized from 250 mL of CH₂Cl₂/hexane 1:10, yielding 8.9 g of 3,6-bis(5,6,7,8-tetrahydronaphthalen-1-yl)-1,2,4,5-tetrazine, as deep purple solid (26%), ¹H NMR (CDCl₃, 400 MHz): chemical shift (ppm) 7.21-7.01 (m, 6H), 2.81-2.72 (m, 4H), 1.76-1.66 (m, 6H).

### Synthesis of Intermediate G

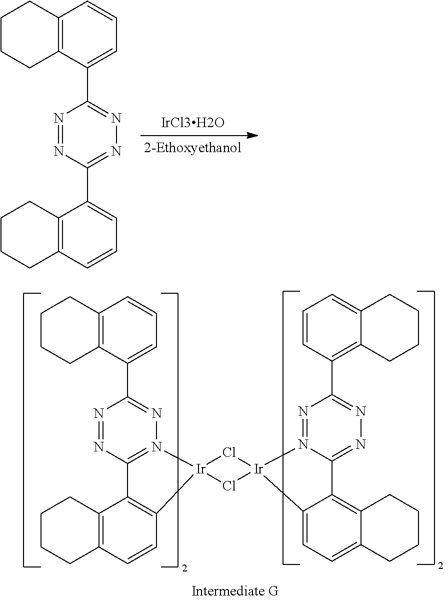

A mixture of 4 g (11.68 mmol) of 3,6-bis(5,6,7,8-tetrahydro-naphthalen-1-yl)-1,2,4,5-tetrazine, 1.9 g (5.31 mmol) of Iridium(III) chloride hydrate, 60 ml of 2-Ethoxyethanol and 20 ml water was degassed and placed under nitrogen, and then heated at 120° C. overnight. After the reaction finished, the mixture was allowed to cool to room temperature. The precipitated product was filtered off with suction and washed with water. Afterwards, 100 ml of water was added and stirred for 1 hr, and then the precipitated product was filtered off with suction. Subsequently, 50 ml of EtOH was added and stirred for 1 hr, and then the precipitated product was filtered off with suction, yielding 2.5 g of Intermediate G, as brown solid (52%)

### Synthesis of Intermediate H

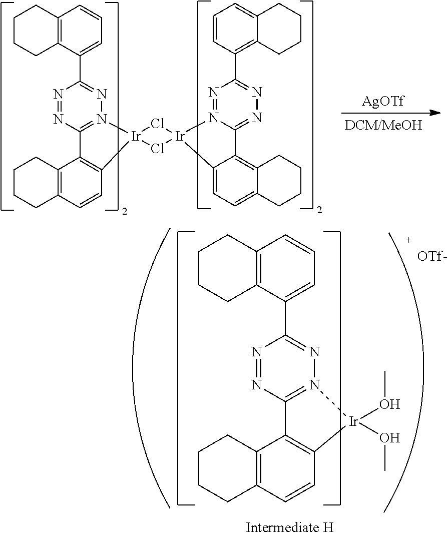

A mixture of 5.0 g (2.7 mmol) of Intermediate G, 1.6 g (6.3 mmol) of silver triflate, 140 ml of dichloromethane and 8 ml of methanol was placed under nitrogen, and then stirred overnight. After the reaction finished, the silver chloride was filtered off and the solvent was evaporated to obtain 4.7 g of iridium triflate precursor, which was used directly in the next step without purification.

### Synthesis of EX51

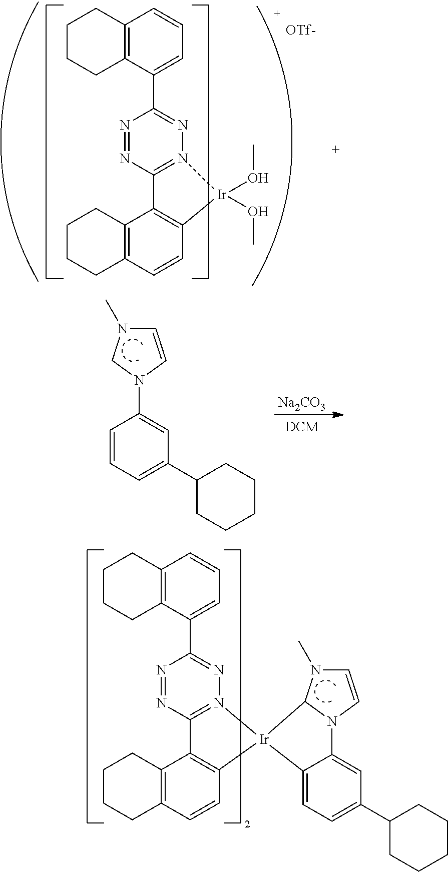

A mixture of 4.7 g (4.3 mmol) of Intermediate H, 1.9 g (8.0 mmol) of 1-(3-cyclohexylphenyl)-3-methyl-2,3-dihydro-1H-imidazole, 70 ml of EtOH and 70 ml of MeOH was placed under nitrogen, and then heated to reflux overnight. After the reaction finished, the mixture was allowed to cool to room temperature. The yellow precipitate formed was filtered under vacuum, washed with ethanol and hexane, and then purified by vacuum sublimation to give 2.8 g (59%) of yellow product EX51. MS (m/z, EI⁺): 1116.49

### Example 15

### Synthesis of EX100

### Synthesis of EX100

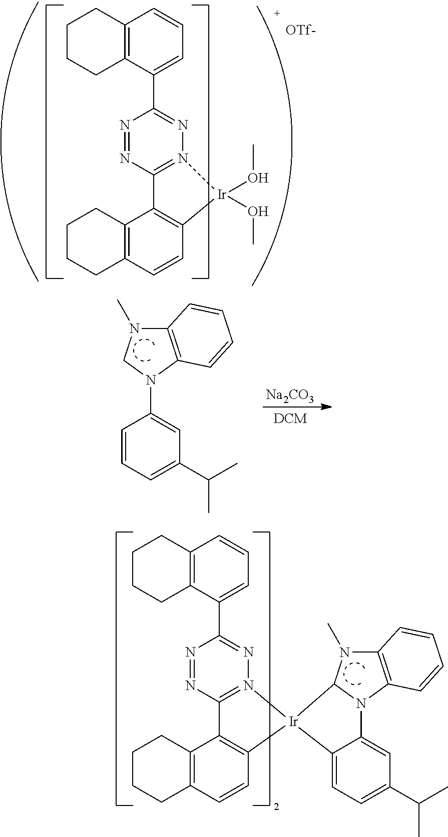

A mixture of 5.3 g (4.8 mmol) of Intermediate H, 2.3 g (8.9 mmol) of 1-(3-isopropylphenyl)-3-methyl-2,3-dihydro-1H-benzo[d]imidazole, 70 ml of EtOH and 70 ml of MeOH was placed under nitrogen, and then heated to reflux overnight. After the reaction finished, the mixture was allowed to cool to room temperature. The yellow precipitate formed was filtered under vacuum, washed with ethanol and hexane, and then purified by vacuum sublimation to give 3.0 g (55%) of yellow product EX100. MS (m/z, EI⁺): 1126.47

### General Method of Producing Organic EL Device

ITO-coated glasses with 9˜12 ohm/square in resistance and 120˜160 nm in thickness are provided (hereinafter ITO substrate) and cleaned in a number of cleaning steps in an ultrasonic bath (e.g. detergent, deionized water). Before vapor deposition of the organic layers, cleaned ITO substrates are further treated by UV and ozone. All pre-treatment processes for ITO substrate are under clean room (class 100).

The organic layers are applied onto the ITO substrate in order by vapor deposition in a high-vacuum unit (10⁻⁷ Torr), such as: resistively heated quartz boats. The thickness of the respective layer and the vapor deposition rate (0.1˜0.3 nm/sec) are precisely monitored or set with the aid of a quartz-crystal monitor. It is also possible, as described above, for individual layers to consist of more than one compound, e.g. a host material doped with a dopant material in the light emitting layer. This is successfully achieved by co-vaporization from two or more sources, which means the iridium complex of the present invention is thermally stable.

Dipyrazino[2,3-f: 2,3-]quinoxaline-2,3,6,7,10,11-hexacarbonitrile (HAT-CN) is used to form the hole injection layer; N,N-bis(naphthalene-1-yl)-N,N-bis(phenyl)-benzidine (NPB) is used to form the hole transporting layer; and N-(biphenyl-4-yl)-9,9-dimethyl-N-(4′-phenyl-biphenyl-4-yl)-9H-fluoren-2-amine (EB2) is used to form the electron blocking layer. The chemical structures of the materials mentioned above are shown below:

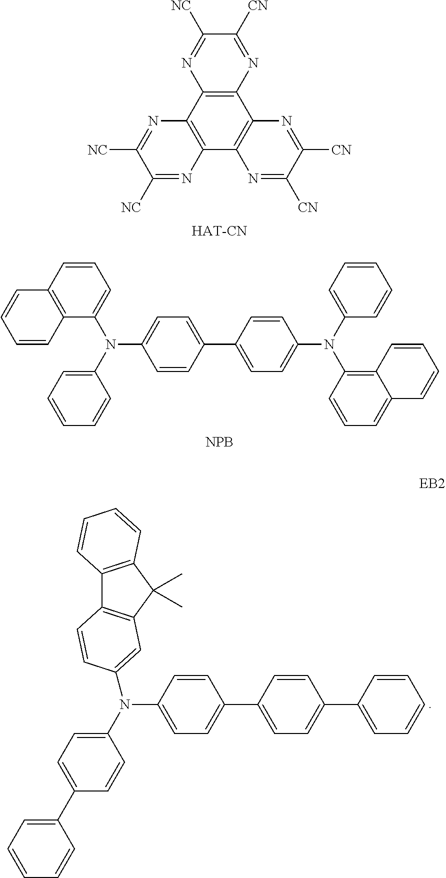

In the present invention, the host material may be selected from the following compounds and a combination thereof:

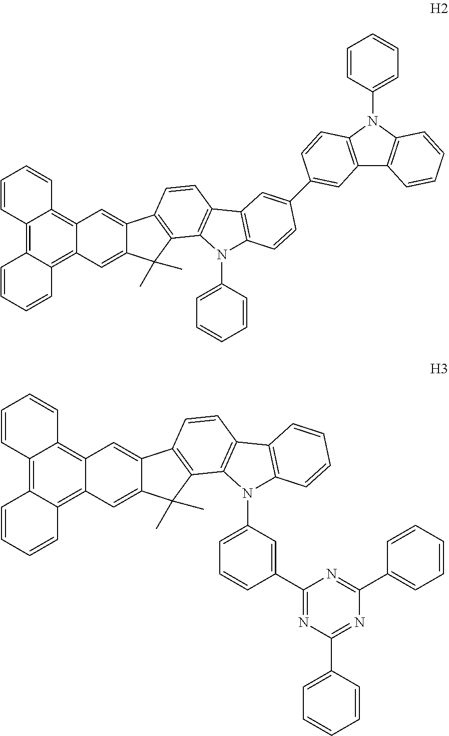 [SMILES: CC1(C)c2cc3c4ccccc4c4ccccc4c3cc2-c2ccc3c4cc(-c5ccc6c(c5)c5ccccc5n6-c5ccccc5)ccc4n(-c4ccccc4)c3c21 ; CC1(C)c2cc3c4ccccc4c4ccccc4c3cc2-c2ccc3c4ccccc4n(-c4cccc(-c5nc(-c6ccccc6)nc(-c6ccccc6)n5)c4)c3c21]

The organic iridium complexes are widely used as phosphorescent dopant for light emitting layer, and Ir(2-phq)₂(acac), YD, and Ir(piq)₂(acac), as shown below, are used as phosphorescent dopant of light emitting layer for comparison in the device test.

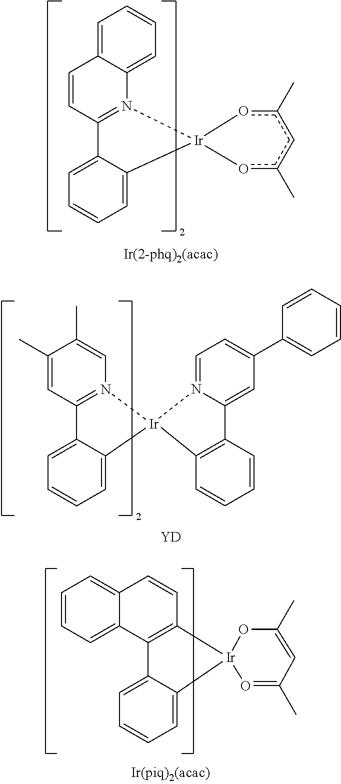

The chemical structures of the exemplary iridium complexes of the present invention for producing exemplary organic EL devices in this invention are shown as follows:

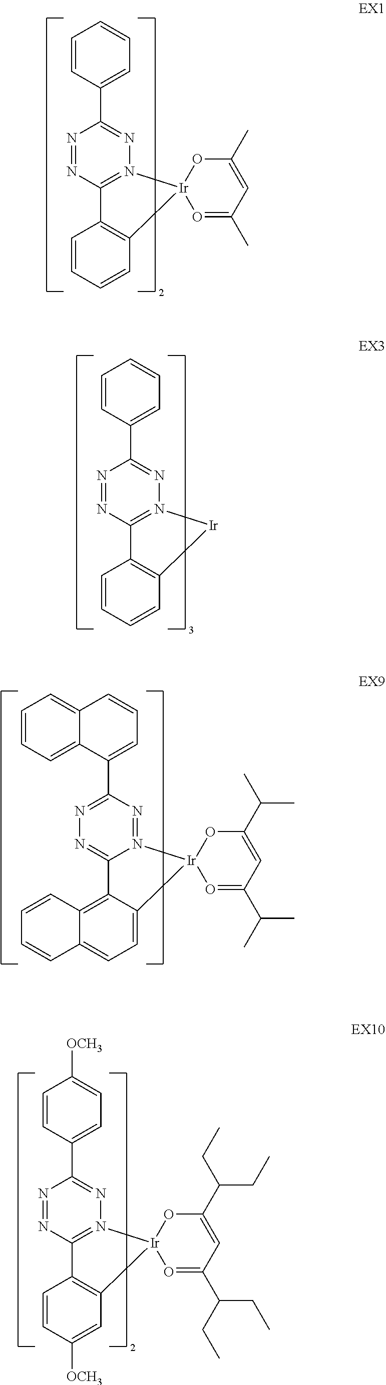

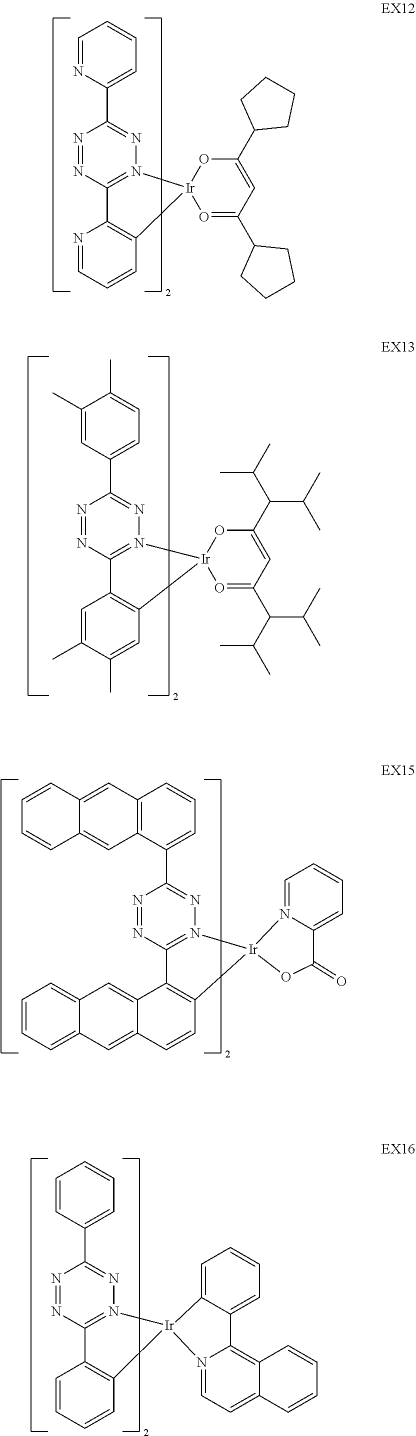

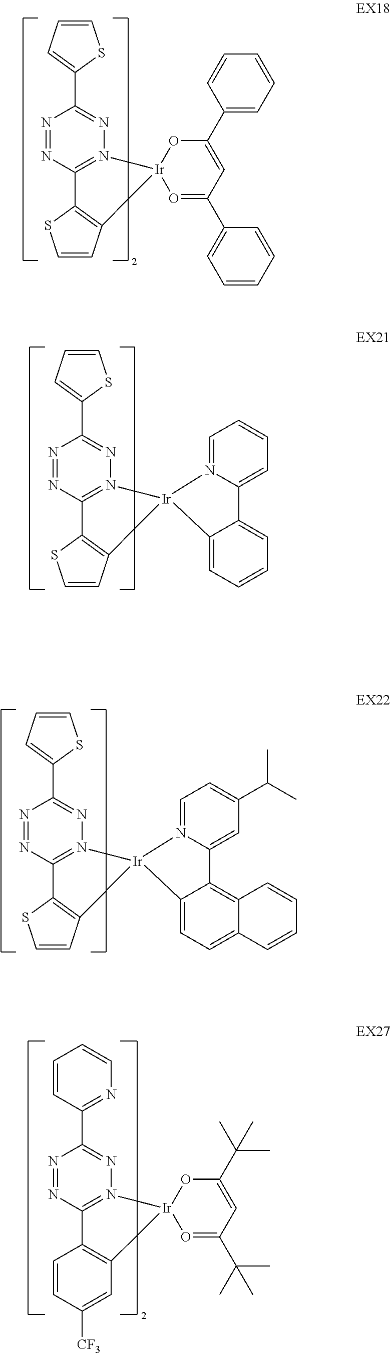

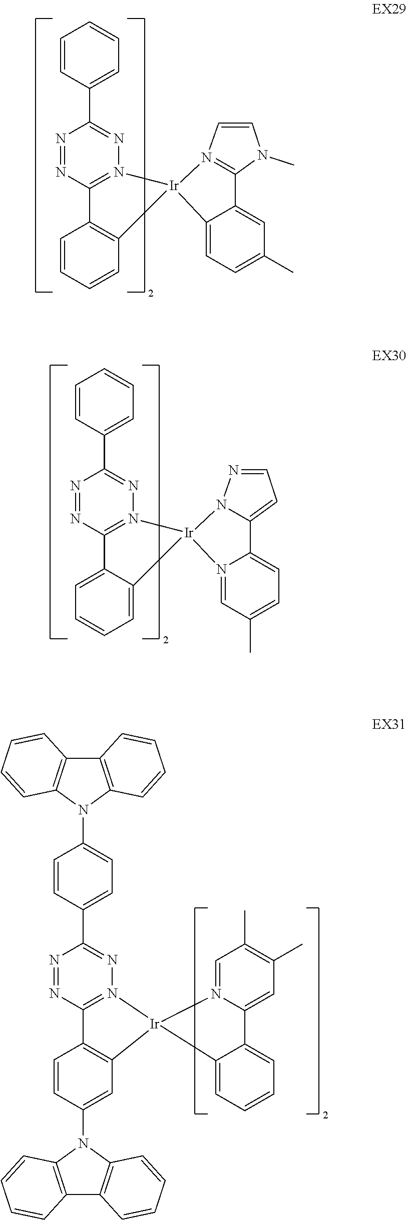

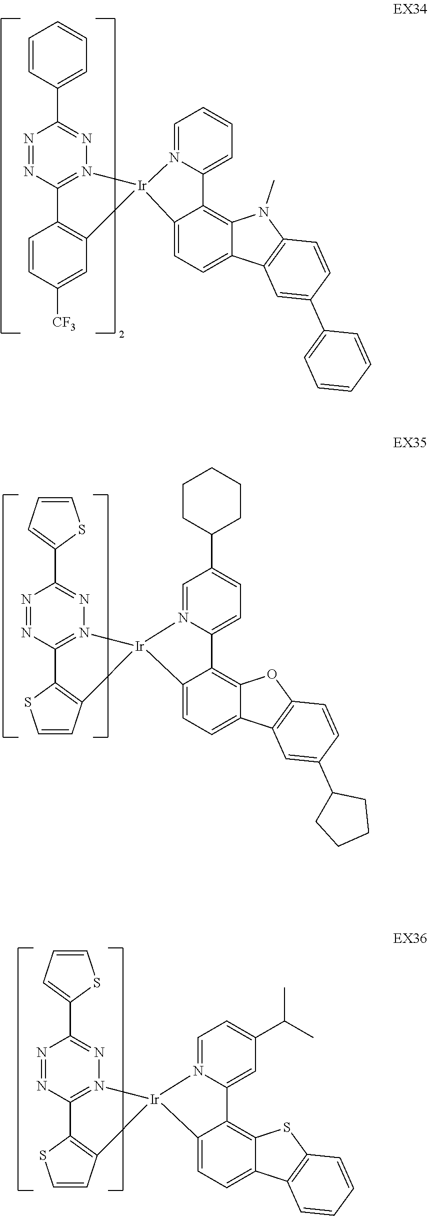

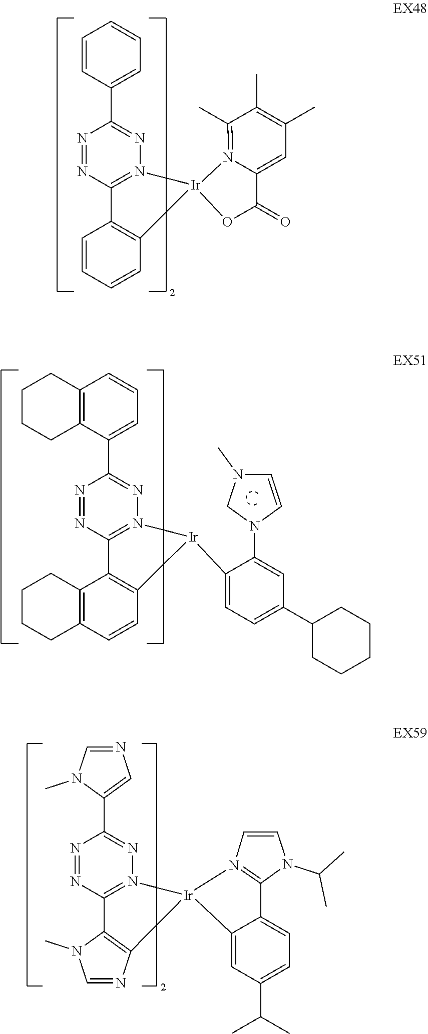

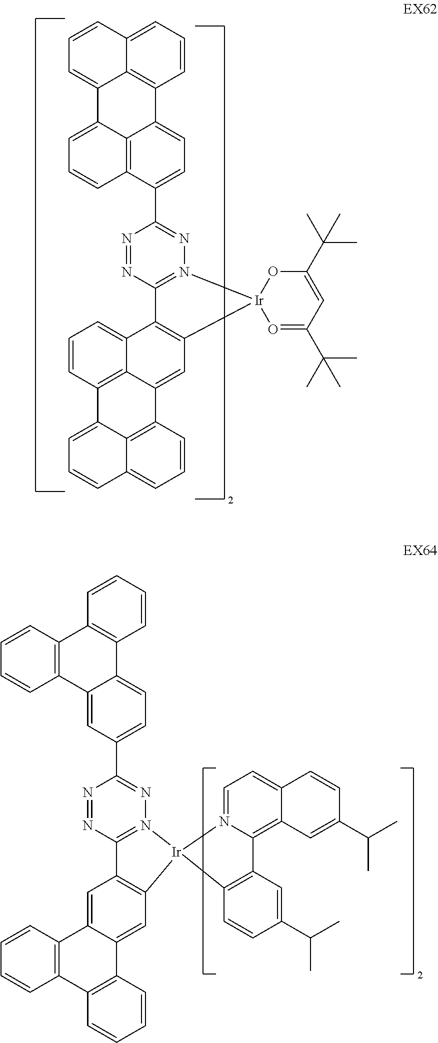

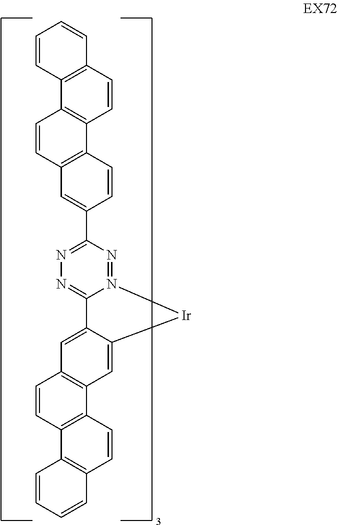

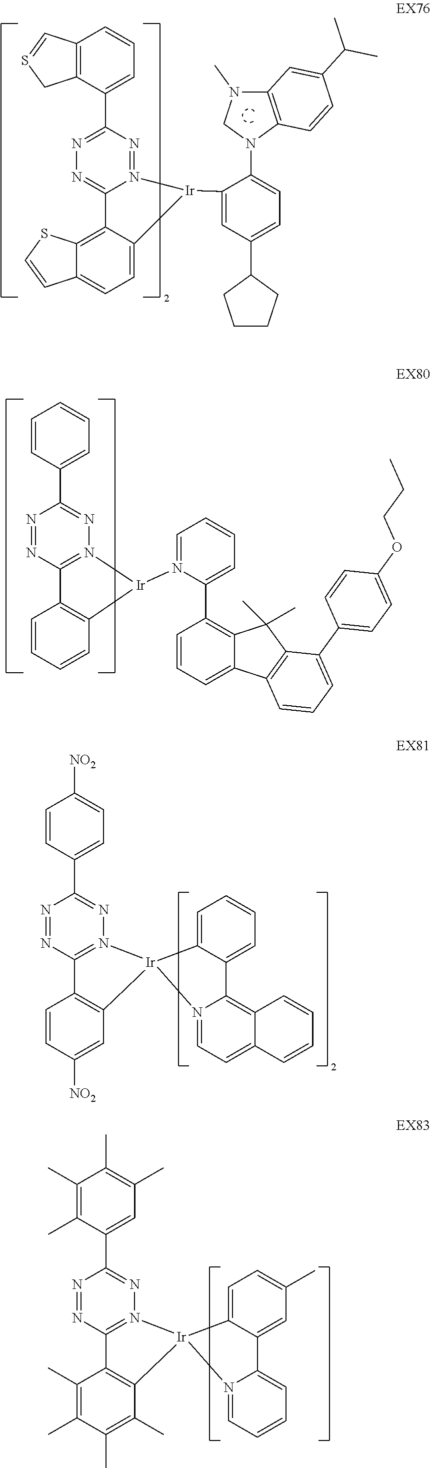

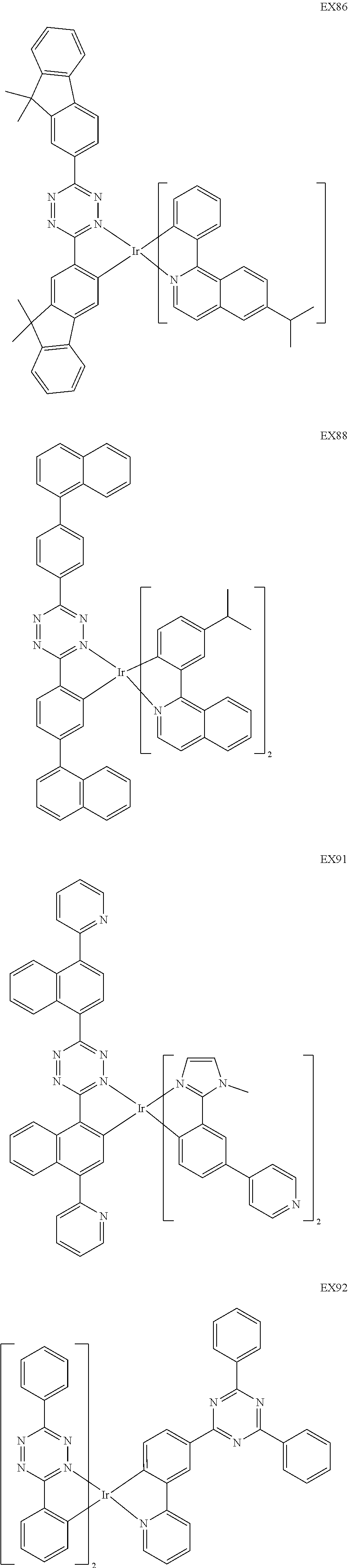

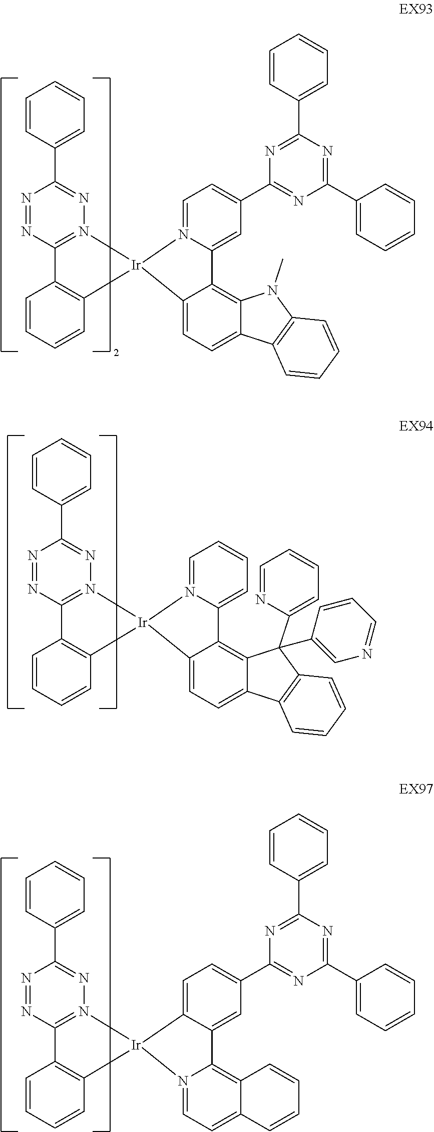

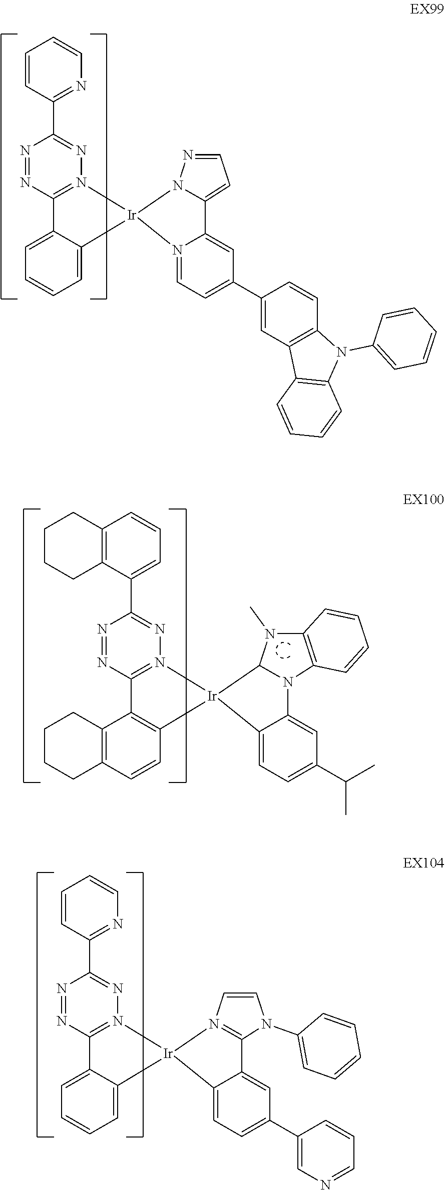

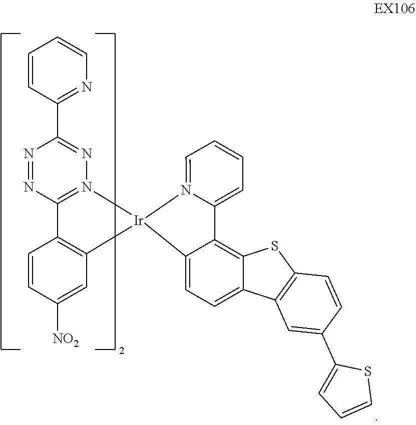

HB3 is used as hole blocking material (HBM), and 2-(10,10-dimethyl-10H-indeno[2,1-b]triphenylen-12-yl)-4,6-diphenyl-1,3,5-triazine (ET2) is used as electron transporting material to co-deposit with 8-hydroxyquinolato-lithium (LiQ) in organic EL devices. The chemical structures of the materials mentioned above are shown below:

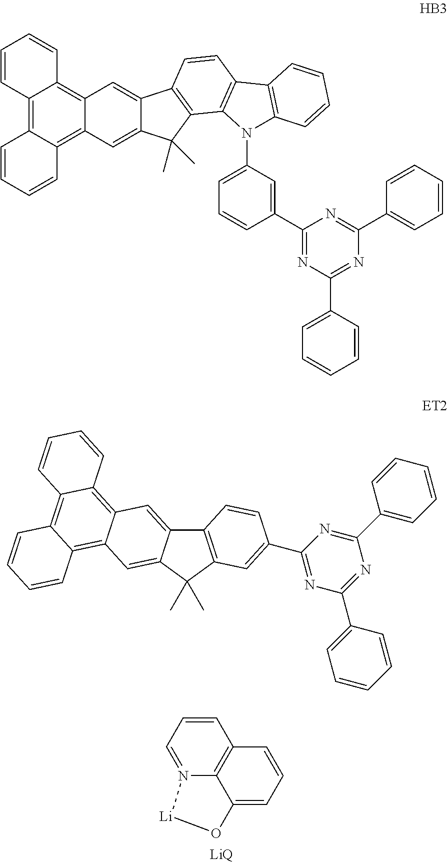

A typical organic EL device consists of low work function metals, such as Al, Mg, Ca, Li and K, as the cathode, and the low work function metals can help electrons injecting the electron transporting layer from cathode. In addition, for reducing the electron injection barrier and improving the organic EL device performance, a thin-film electron injecting layer is introduced between the cathode and the electron transporting layer. Conventional materials of electron injecting layer are metal halide or metal oxide with low work function, such as: LiF, LiQ, MgO, or Li₂O. On the other hand, after the organic EL device fabrication, EL spectra and CIE coordination are measured by using a PR650 spectra scan spectrometer. Furthermore, the current/voltage, luminescence/voltage and yield/voltage characteristics are taken with a Keithley 2400 programmable voltage-current source. The above-mentioned apparatuses are operated at room temperature (about 25° C.) and under atmospheric pressure.

### Example 16

Using a procedure analogous to the above mentioned general method, organic EL devices emitting phosphorescence and having the following device structure (as shown in the FIGURE) were produced: ITO/HAT-CN (20 nm)/NPB (110 nm)/EB2(5 nm)/H2 and H3 doped with 15% phosphorescent dopant (30 nm)/HB3 (10 nm)/ET2 doped with 40% LiQ (35 nm)/LiQ (1 nm)/Al (160 nm). In the device illustrated in the FIGURE, the hole injection layer 20 is deposited onto the transparent electrode 10, the hole transport layer 30 is deposited onto the hole injection layer 20, the electron blocking layer 40 is deposited onto the hole transport layer 30, the phosphorescence emitting layer 50 is deposited onto the electron blocking layer 40, the hole blocking layer 60 is deposited onto the phosphorescence emitting layer 50, the electron transport layer 70 is deposited onto the hole blocking layer 60, the electron injection layer 80 is deposited onto the electron transport layer 70, and the metal electrode 90 is deposited onto the electron injection layer 80. The I-V-B (at 1000 nits) and half-life time test reports of these organic EL devices are summarized in Table 1 below. The half-life time is defined as the time the initial luminance of 1000 cd/m² has dropped to half.

TABLE 1

| | | | | | Half-life |
|---|---|---|---|---|---|
| | | Voltage | Efficiency | | time |
| Host | Dopant | (V) | (cd/A) | Color | (hour) |
| H2 + H3 | Ir(2-phq)₂(acac) | 4.7 | 19 | Red | 450 |
| H2 + H3 | EX1 | 4.4 | 22 | Red | 720 |
| H2 + H3 | EX9 | 4.5 | 21 | Red | 700 |
| H2 + H3 | EX10 | 4.4 | 22 | Red | 710 |
| H2 + H3 | EX12 | 4.2 | 23 | Red | 740 |
| H2 + H3 | EX13 | 4.4 | 21 | Red | 730 |
| H2 + H3 | EX16 | 4.0 | 25 | Red | 780 |
| H2 + H3 | EX18 | 4.3 | 22 | Red | 730 |
| H2 + H3 | EX27 | 4.2 | 23 | Red | 750 |
| H2 + H3 | EX35 | 4.6 | 19 | Red | 650 |
| H2 + H3 | EX62 | 4.5 | 20 | Red | 690 |
| H2 + H3 | EX64 | 4.7 | 20 | Red | 670 |
| H2 + H3 | EX81 | 4.5 | 21 | Red | 710 |
| H2 + H3 | EX86 | 4.6 | 19 | Red | 640 |
| H2 + H3 | EX88 | 4.6 | 20 | Red | 660 |
| H2 + H3 | EX97 | 4.7 | 19 | Red | 630 |
| H2 + H3 | Ir(piq)₂(acac) | 4.9 | 16 | Red | 370 |
| H2 + H3 | EX34 | 4.3 | 21 | Red | 680 |
| H2 + H3 | EX36 | 4.6 | 19 | Red | 590 |
| H2 + H3 | EX51 | 4.5 | 22 | Red | 630 |
| H2 + H3 | EX76 | 4.4 | 21 | Red | 620 |
| H2 + H3 | EX80 | 4.6 | 18 | Red | 600 |
| H2 + H3 | EX93 | 4.6 | 19 | Red | 590 |
| H2 + H3 | EX94 | 4.7 | 18 | Red | 580 |
| H2 + H3 | EX100 | 4.5 | 22 | Red | 640 |
| H2 + H3 | EX106 | 4.7 | 17 | Red | 560 |
| H2 + H3 | YD | 4.8 | 39 | Yellow | 320 |
| H2 + H3 | EX3 | 4.6 | 43 | Yellow | 500 |
| H2 + H3 | EX15 | 4.5 | 42 | Yellow | 470 |
| H2 + H3 | EX21 | 4.7 | 41 | Yellow | 450 |
| H2 + H3 | EX22 | 4.7 | 42 | Yellow | 460 |
| H2 + H3 | EX29 | 4.4 | 46 | Yellow | 530 |
| H2 + H3 | EX30 | 4.5 | 44 | Yellow | 520 |
| H2 + H3 | EX31 | 4.5 | 41 | Yellow | 450 |
| H2 + H3 | EX48 | 4.6 | 42 | Yellow | 480 |
| H2 + H3 | EX59 | 4.7 | 40 | Yellow | 390 |
| H2 + H3 | EX72 | 4.7 | 39 | Yellow | 380 |
| H2 + H3 | EX83 | 4.6 | 42 | Yellow | 490 |
| H2 + H3 | EX91 | 4.6 | 41 | Yellow | 440 |
| H2 + H3 | EX92 | 4.5 | 42 | Yellow | 490 |
| H2 + H3 | EX99 | 4.6 | 41 | Yellow | 450 |
| H2 + H3 | EX104 | 4.5 | 41 | Yellow | 480 |

In In Table 1, we show that the iridium complex of formula (1) used as the dopant material of light emitting layer for organic EL device of the present invention exhibits better performance than the prior art organic EL materials. More specifically, the organic EL devices of the present invention use the iridium complex of formula (1) as light emitting dopant material to collocate with the co-host material (i.e. H2 and H3), showing reduced power consumption, increased current efficiency, and extended half-life time.

To sum up, the present invention discloses an iridium complex, which can be used as the phosphorescent dopant material of the light emitting layer in organic EL devices. The mentioned iridium complex is represented by the following formula (1):

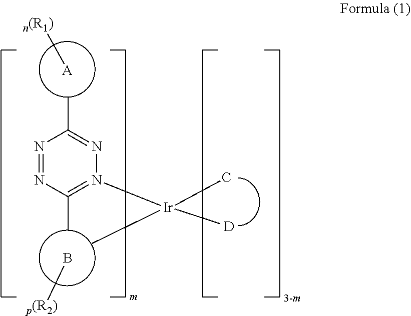

wherein C-D represents a bidentate ligand; ring A and ring B independently represent a fused ring unit with one to five rings; m represents an integer of 1 to 3; n and p independently represent an integer of 1 to 4; R₁ to R₂ are independently a hydrogen atom, a halogen, NO₂, a substituted or unsubstituted alkyl group having 1 to 30 carbon atoms, a substituted or unsubstituted alkoxy group having 1 to 30 carbon atoms, a substituted or unsubstituted aryl group having 6 to 30 carbon atoms, a substituted or unsubstituted aralkyl group having 6 to 30 carbon atoms, or a substituted or unsubstituted heteroaryl group having 3 to 30 carbon atoms.

Obviously, many modifications and variations are possible in light of the above teachings. It is therefore to be understood that within the scope of the appended claims the present invention can be practiced otherwise than as specifically described herein. Although specific embodiments have been illustrated and described herein, it is obvious to those skilled in the art that many modifications of the present invention may be made without departing from what is intended to be limited solely by the appended claims.

What is claimed is:

1. An iridium complex of formula (1): 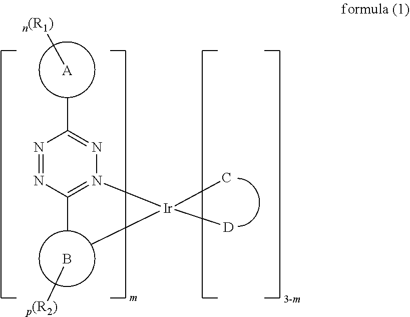
wherein C-D represents a bidentate ligand; ring A and ring B independently represent a fused ring unit with one to five rings; m represents an integer of 1 to 3; n and p independently represent an integer of 1 to 4; R₁ to R₂ are independently a hydrogen atom, a halogen, NO₂, a substituted or unsubstituted alkyl group having 1 to 30 carbon atoms, a substituted or unsubstituted alkoxy group having 1 to 30 carbon atoms, a substituted or unsubstituted aryl group having 6 to 30 carbon atoms, a substituted or unsubstituted aralkyl group having 6 to 30 carbon atoms, or a substituted or unsubstituted heteroaryl group having 3 to 30 carbon atoms.

2. The iridium complex according to claim 1, wherein the bidentate ligand has one of the following formulas: 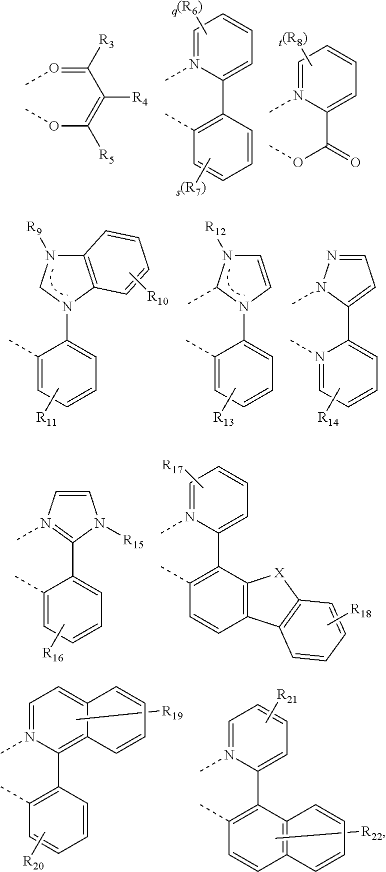
wherein X represents O, S, Se, CR₂₃R₂₄, NR₂₅ or SiR₂₆R₂₇; q, s, and t independently represent an integer of 1 to 4; and R₃ to R₂₇ are independently a hydrogen atom, a halogen, a substituted or unsubstituted alkyl group having 1 to 30 carbon atoms, a substituted or unsubstituted cycloalkyl group having 1 to 30 carbon atoms, a substituted or unsubstituted aryl group having 6 to 30 carbon atoms, a substituted or unsubstituted aralkyl group having 6 to 30 carbon atoms, or a substituted or unsubstituted heteroaryl group having 3 to 30 carbon atoms.

3. The iridium complex according to claim 2, wherein R₃ to R₂₂ are independently a hydrogen atom, a methyl group, an isopropyl group, an isobutyl group, a cyclopentyl group, a hexyl group, a cyclohexyl group, or a phenyl group.

4. The iridium complex according to claim 1, wherein ring A and ring B independently represent a phenyl group, a naphthyl group, a anthracenyl group, a phenanthrenyl group, a pyrenyl group, a chrysenyl group, a triphenylenyl group, a perylenyl group, an imidazole group, a pyridine group, an isoquinoline group, a thiophenyl group, or a benzothiophenyl group.

5. The iridium complex according to claim 1, wherein the iridium complex is one of the following compounds:

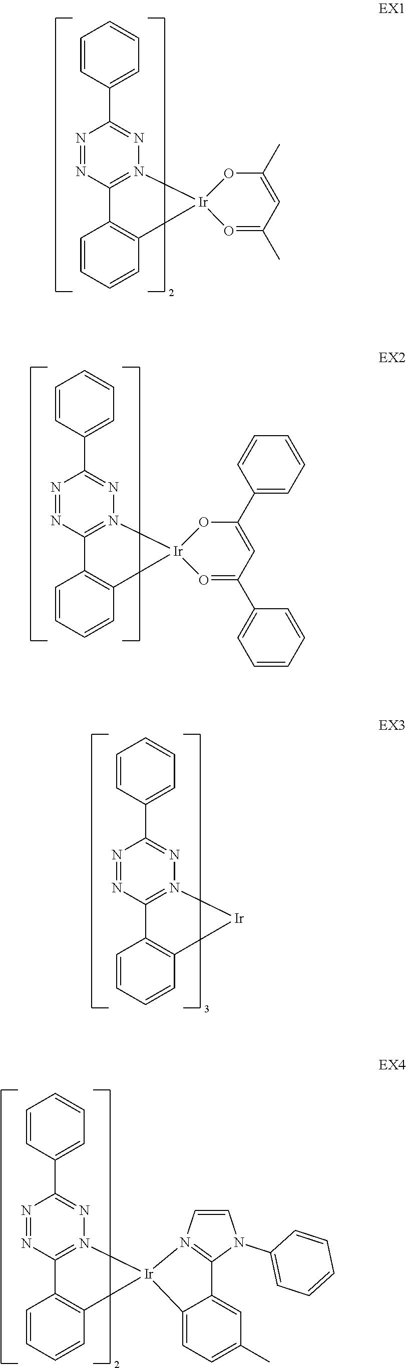

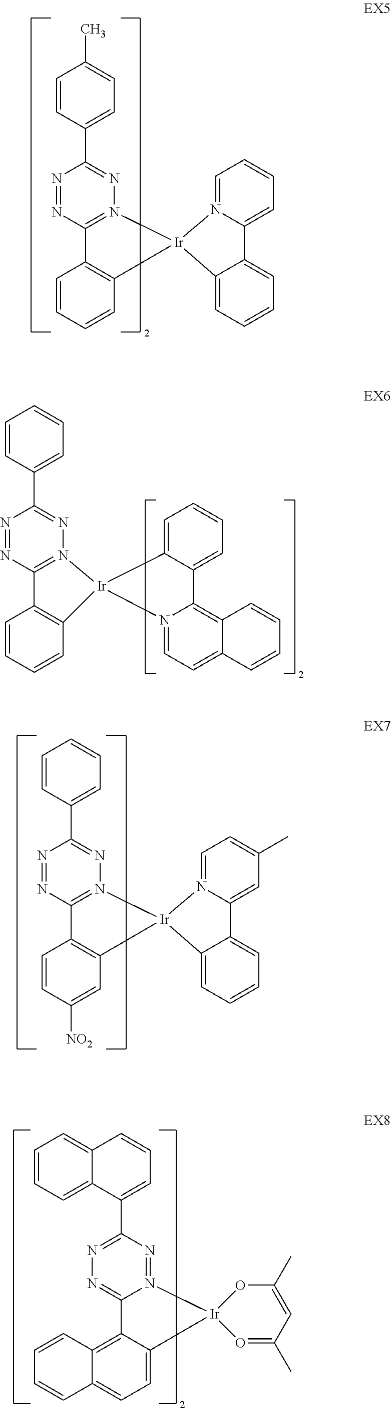

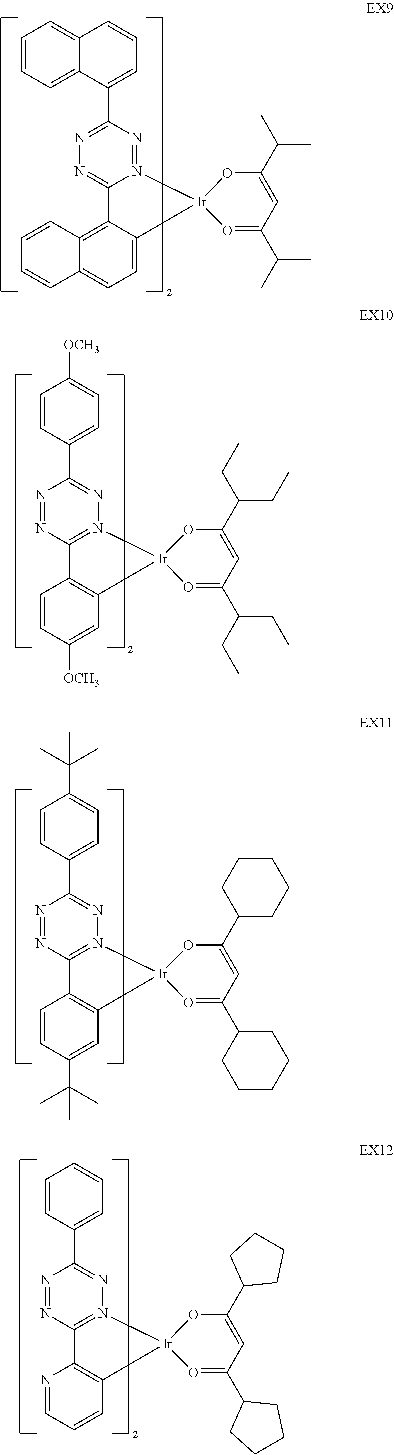

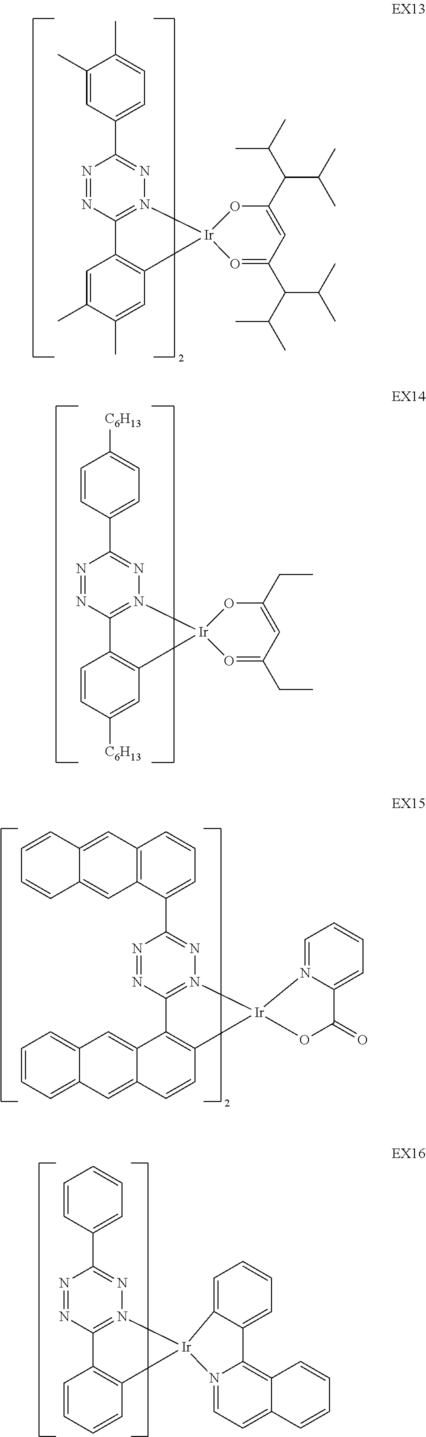

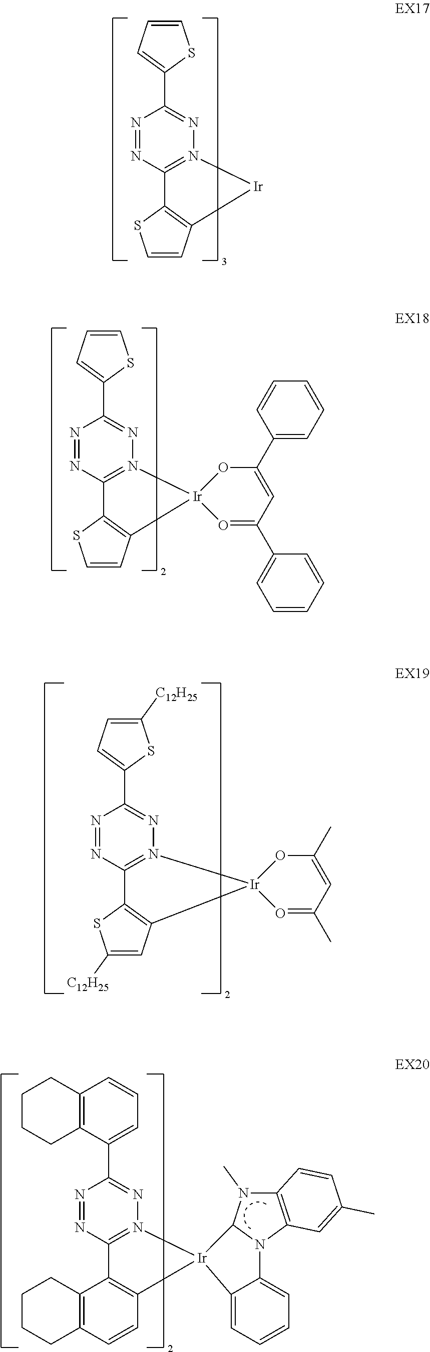

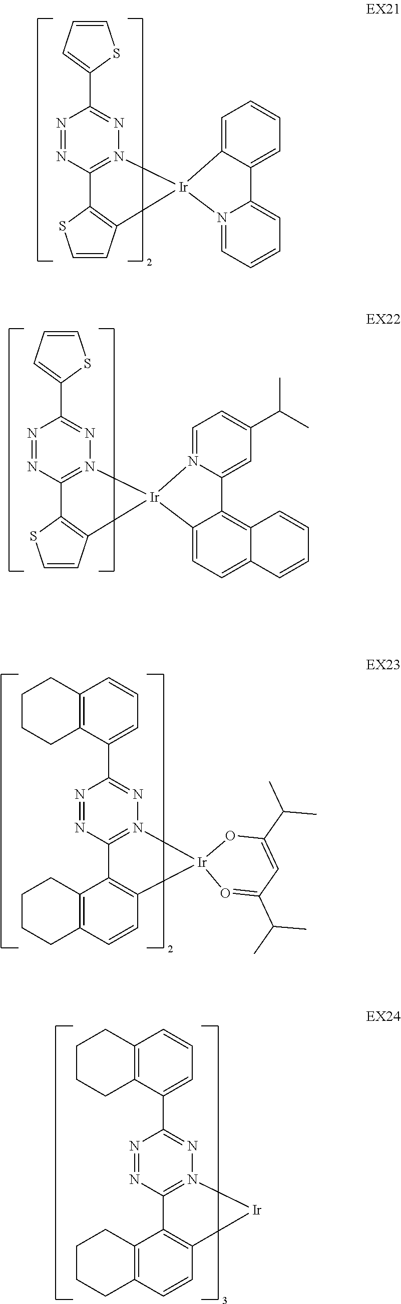

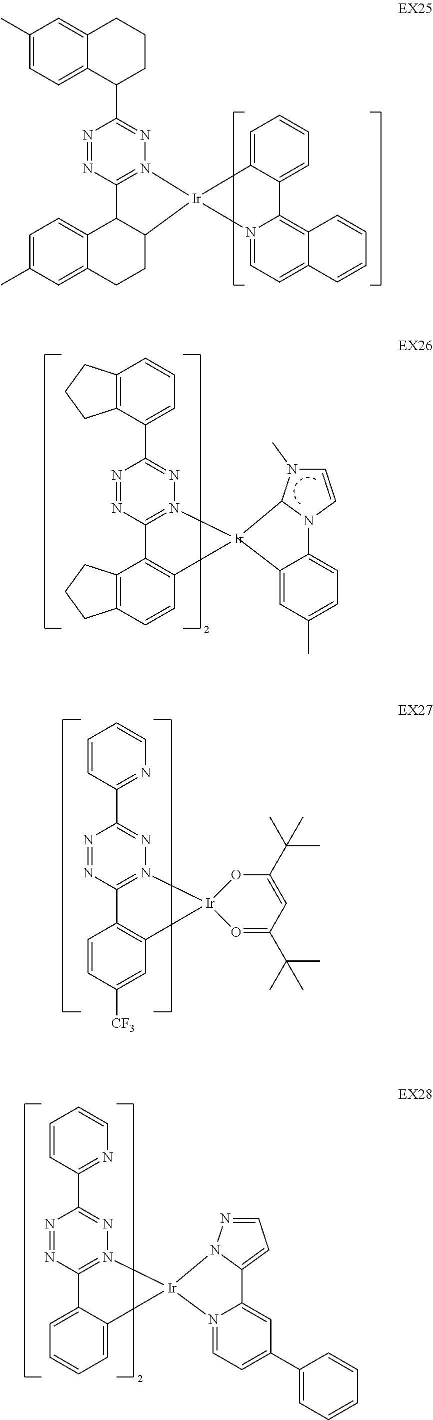

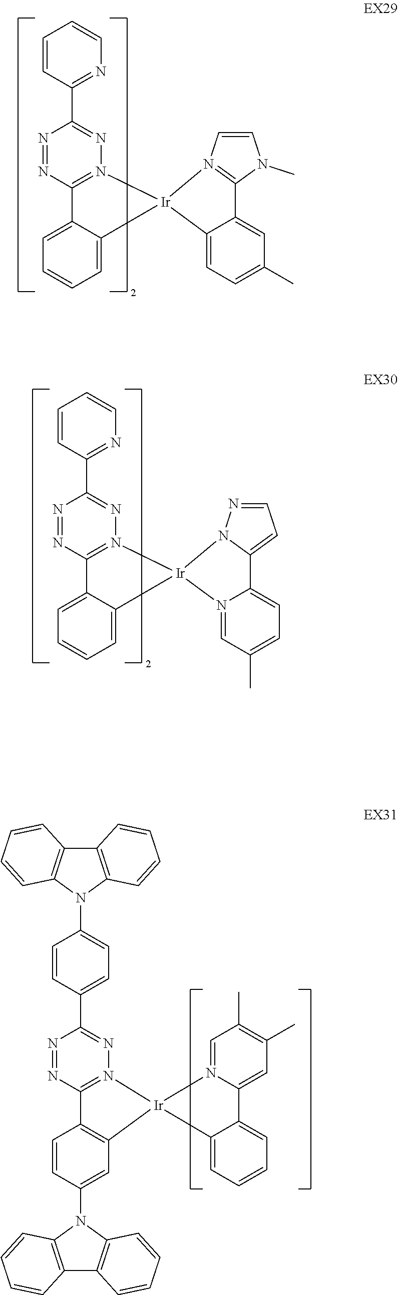

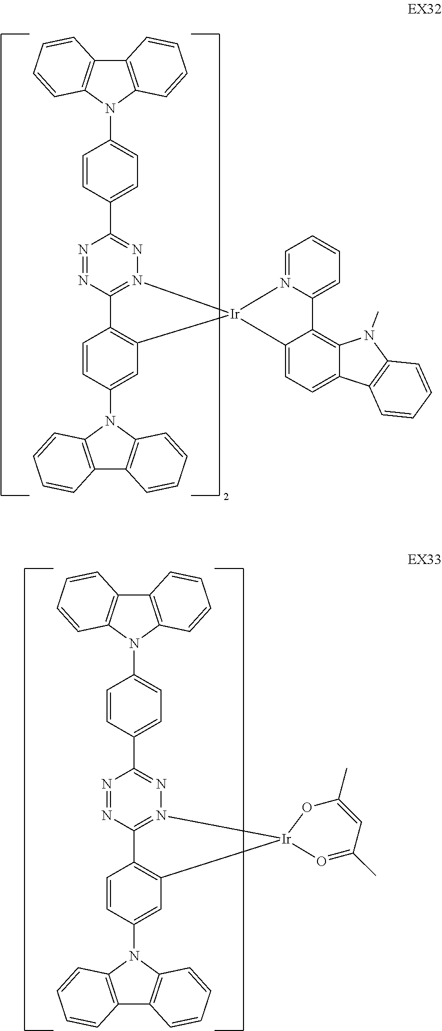

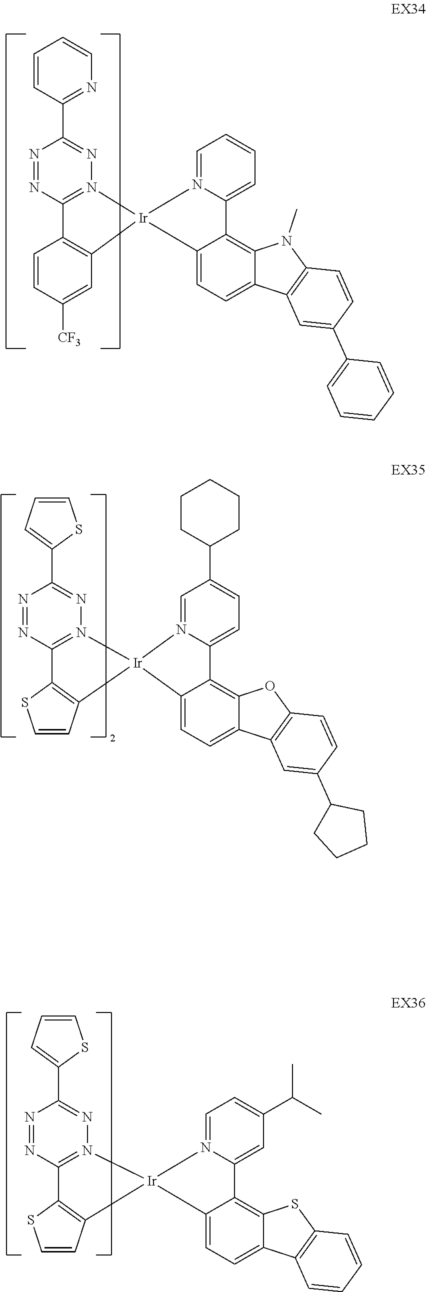

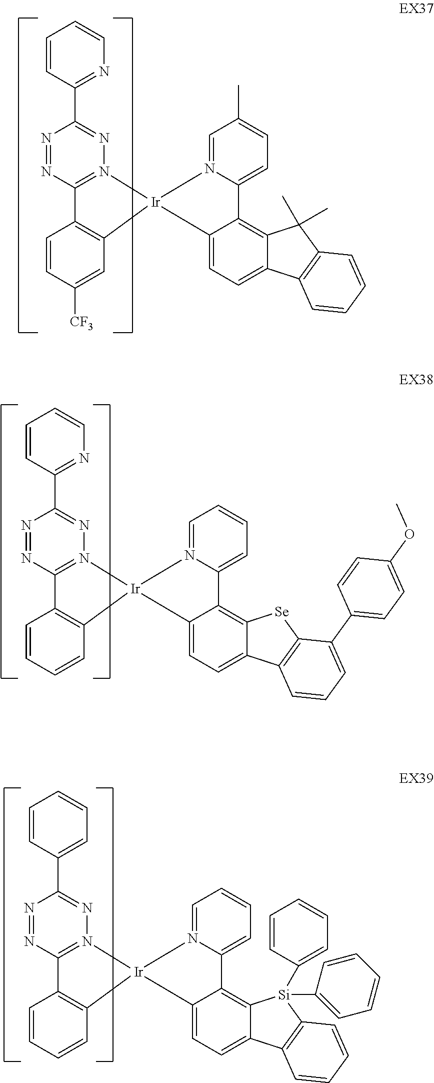

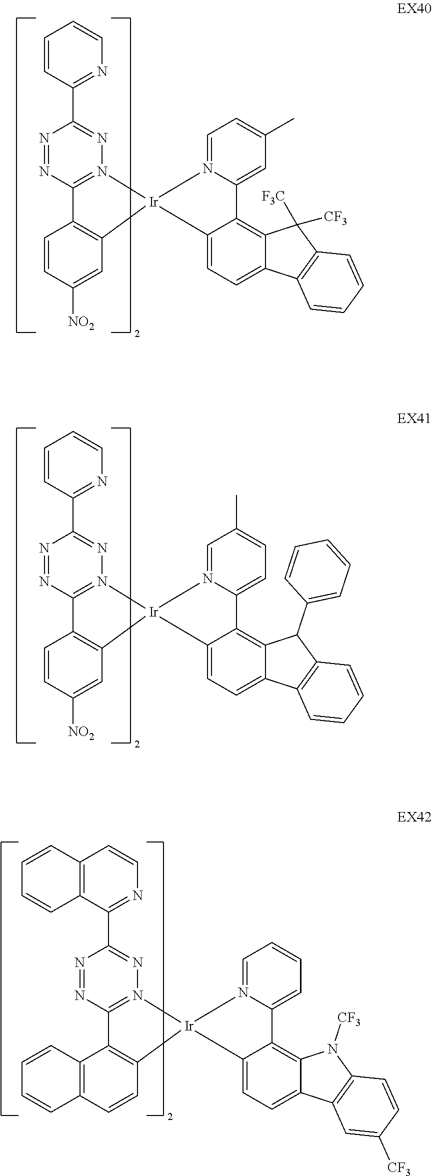

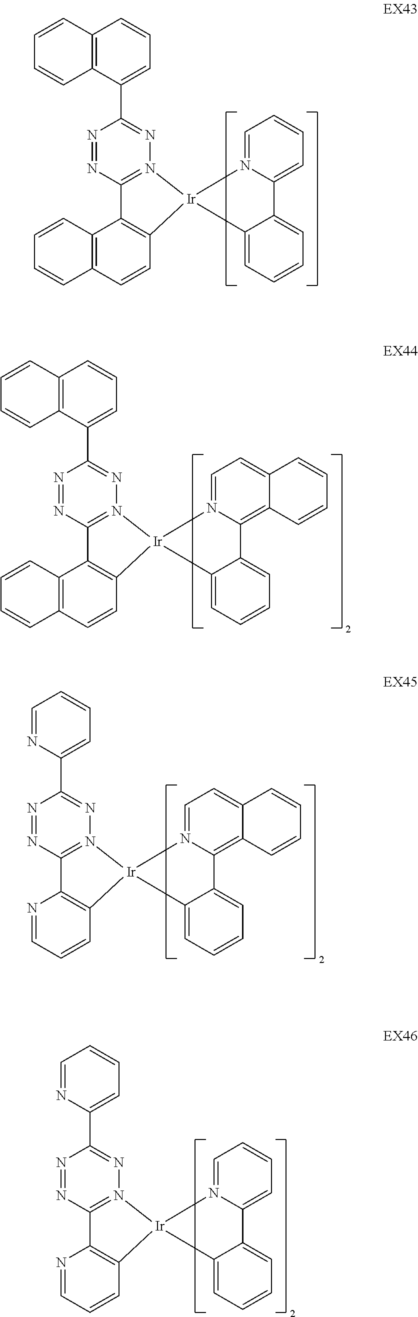

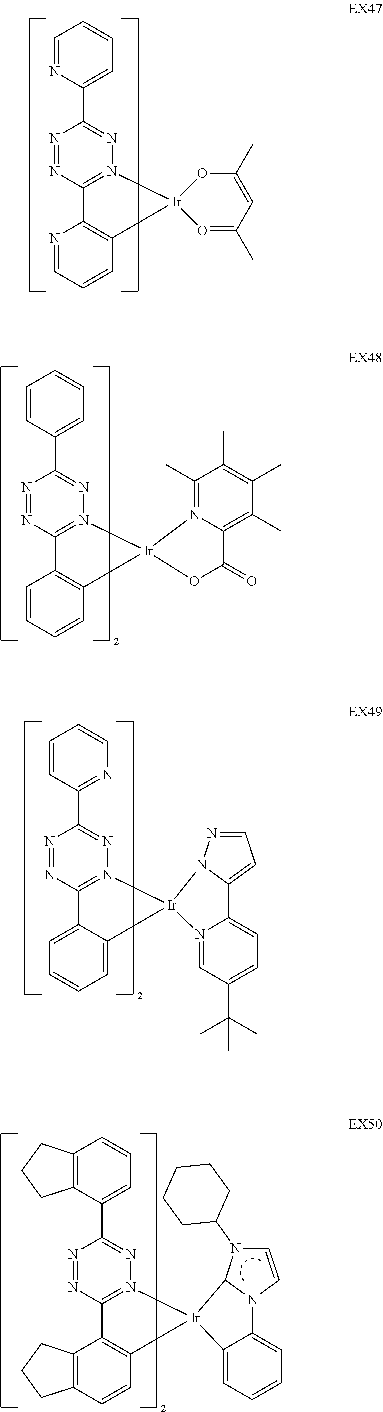

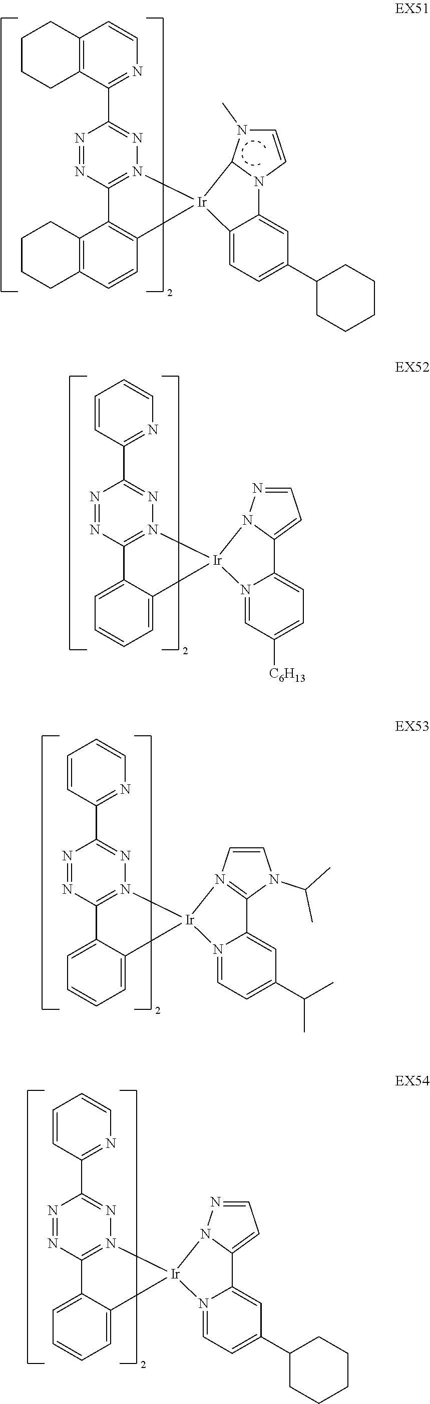

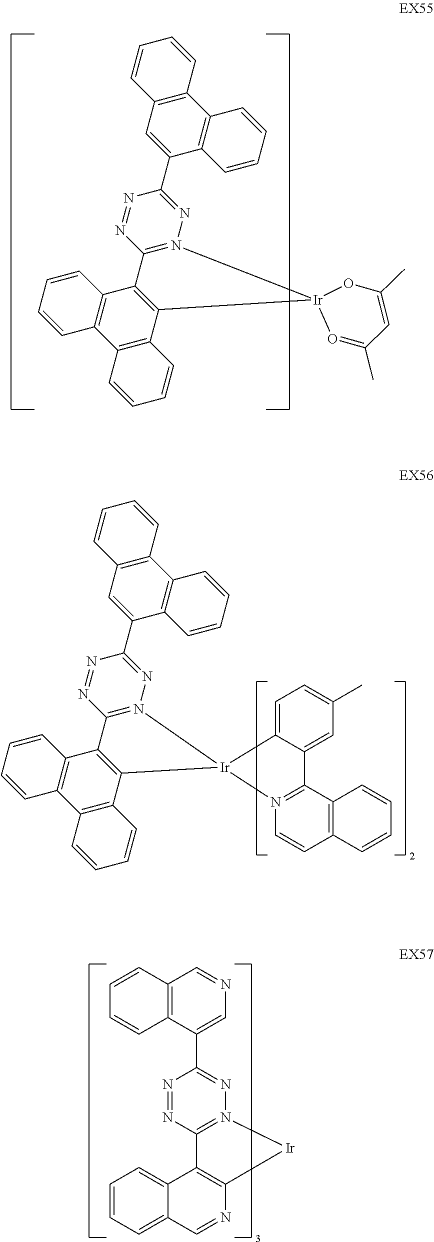

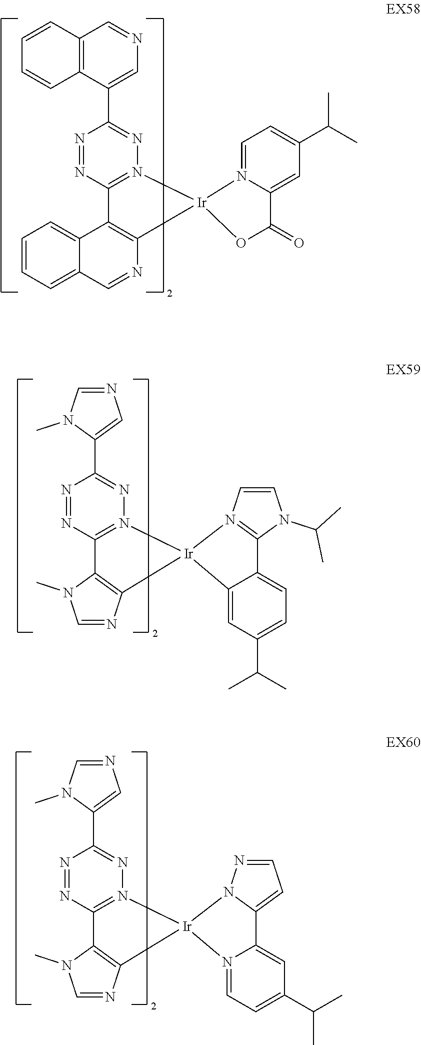

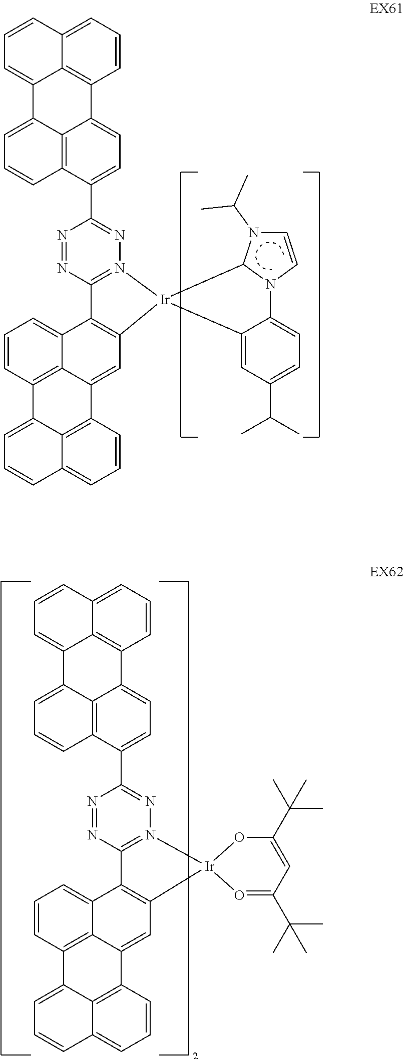

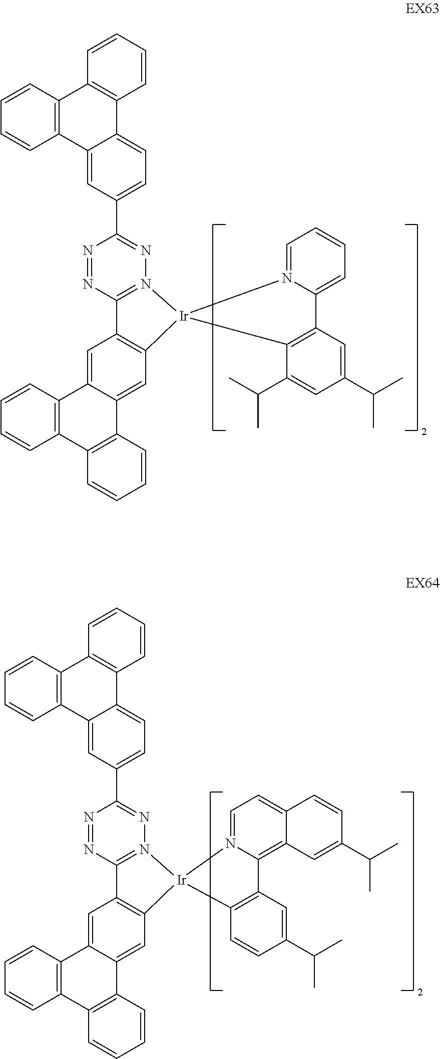

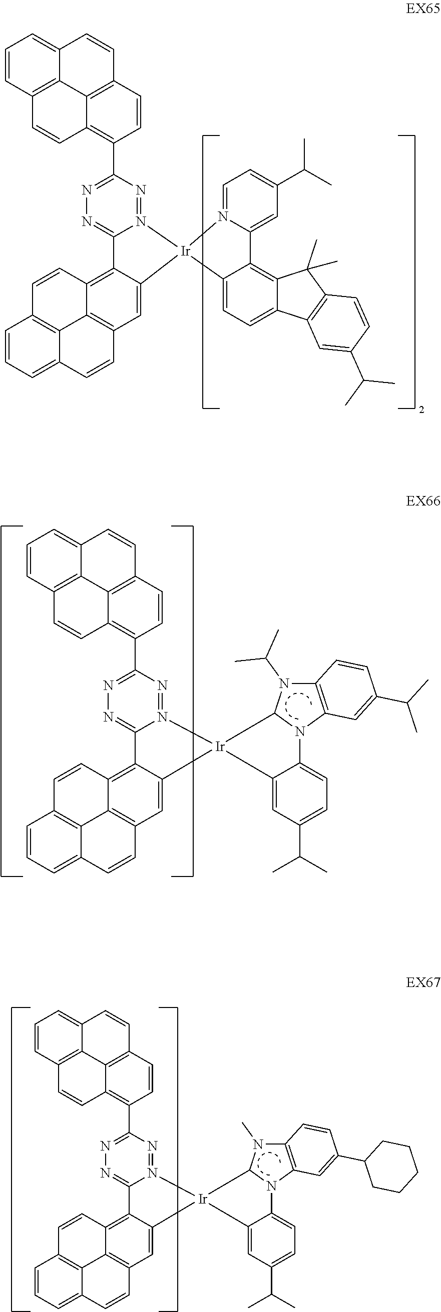

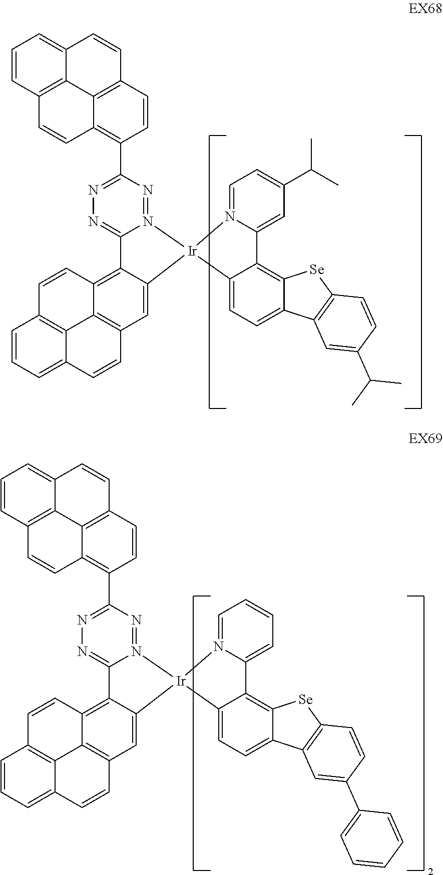

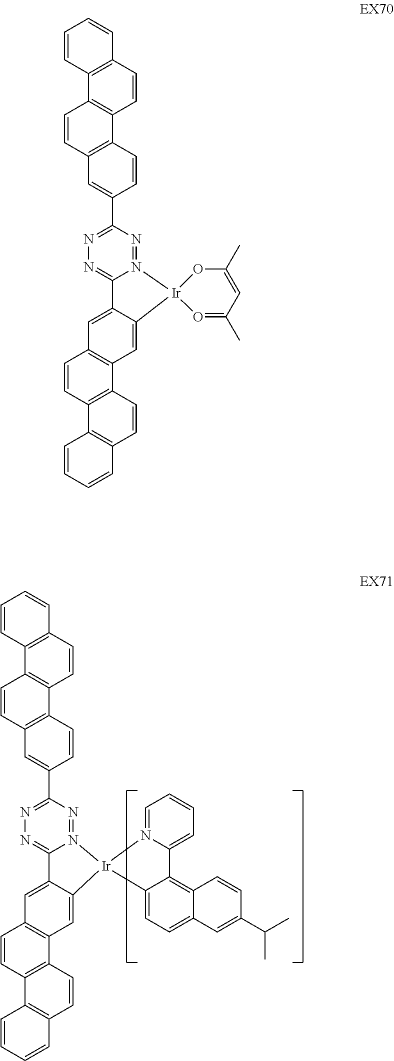

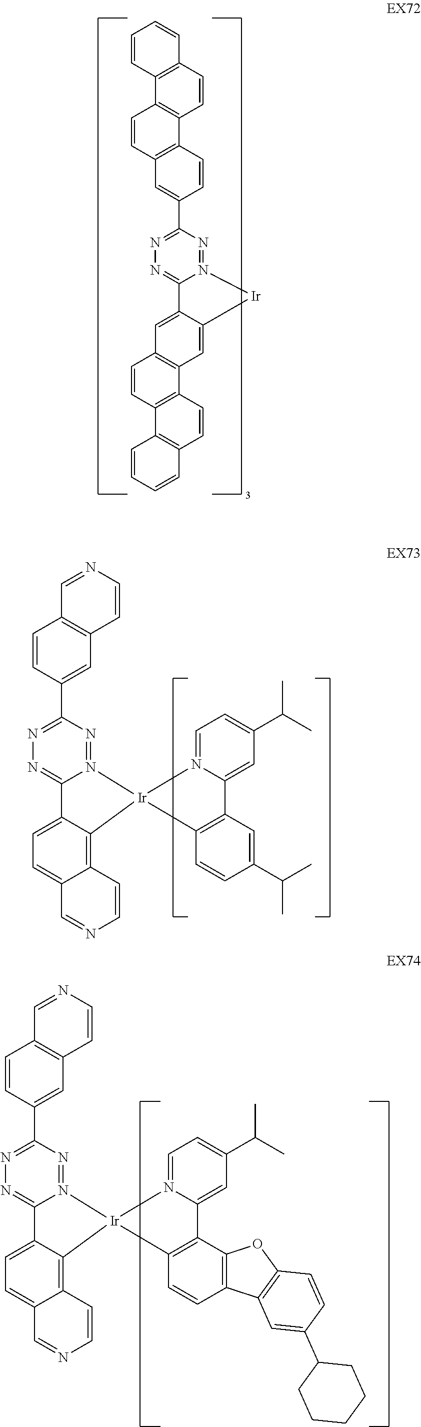

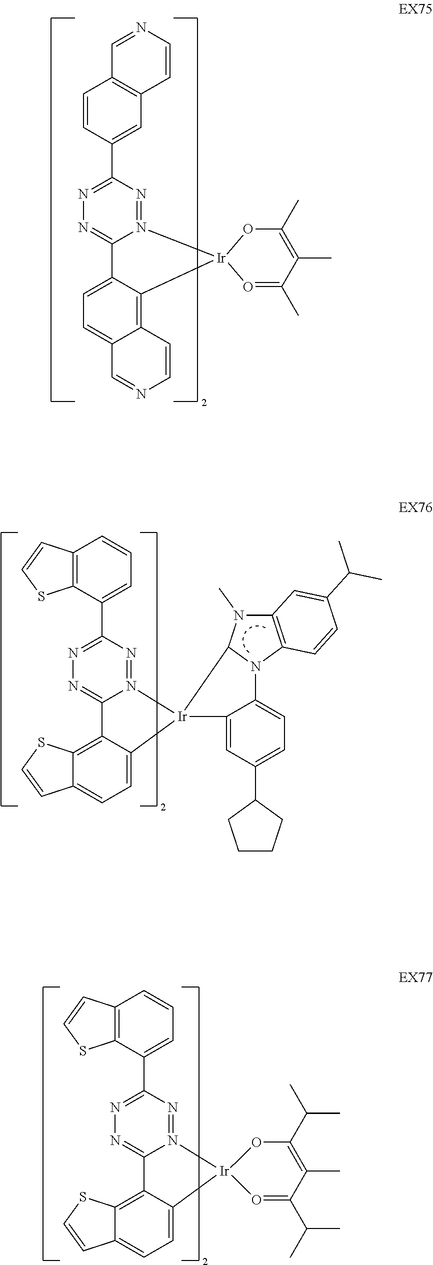

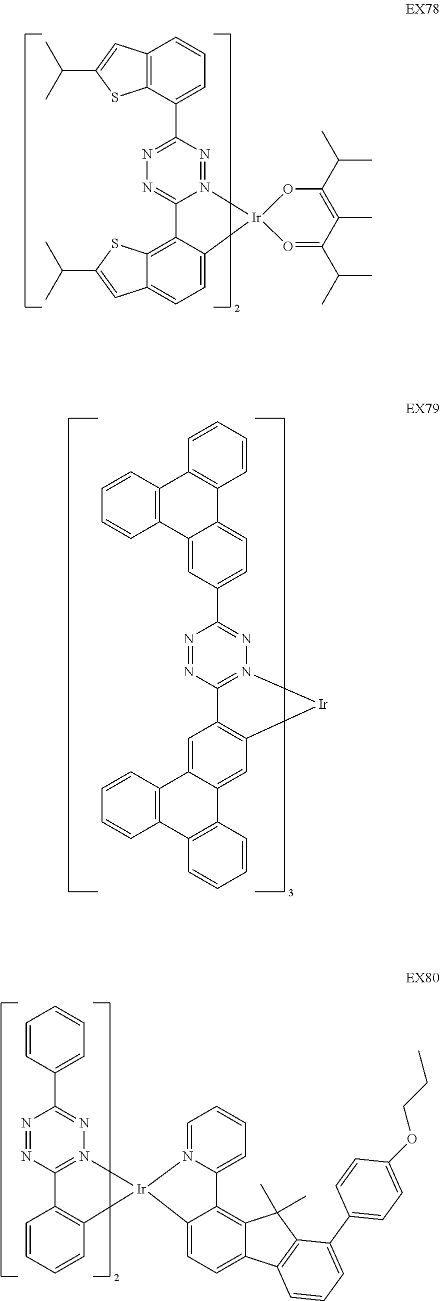

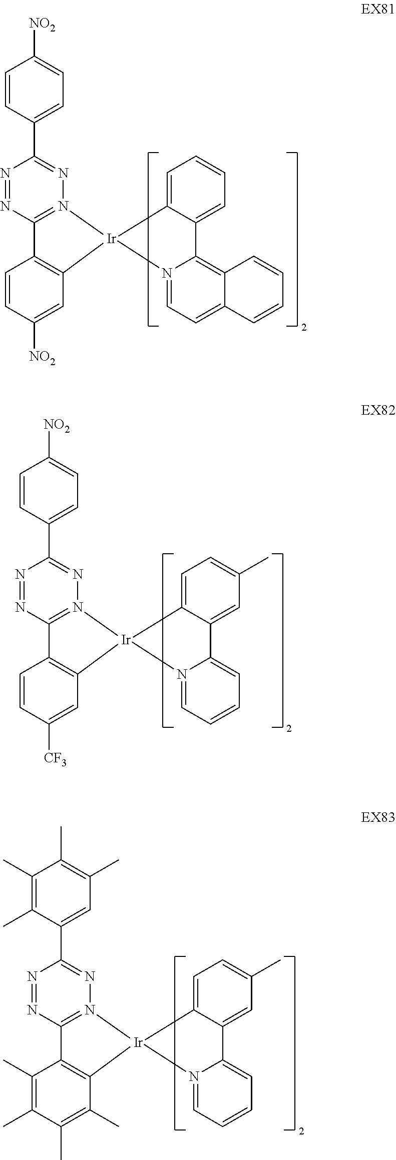

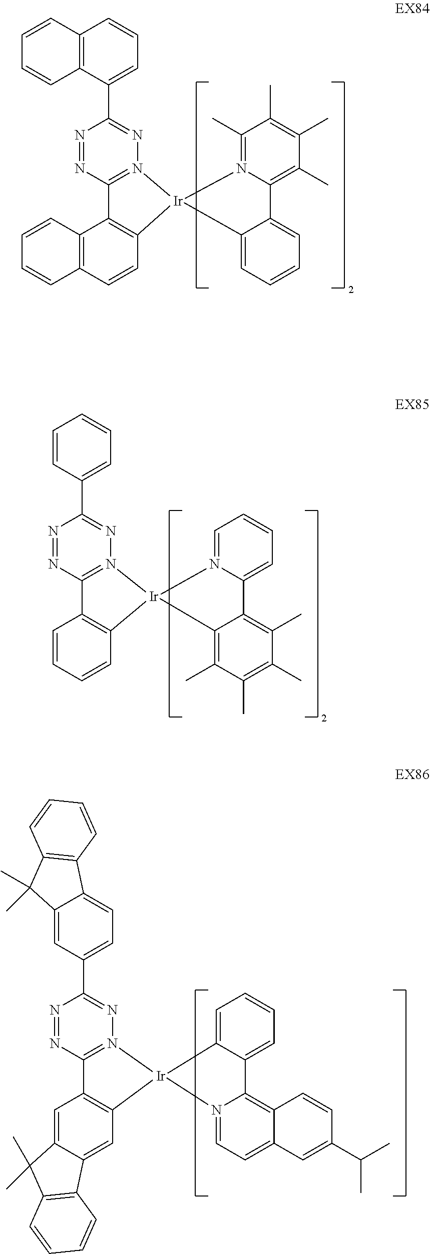

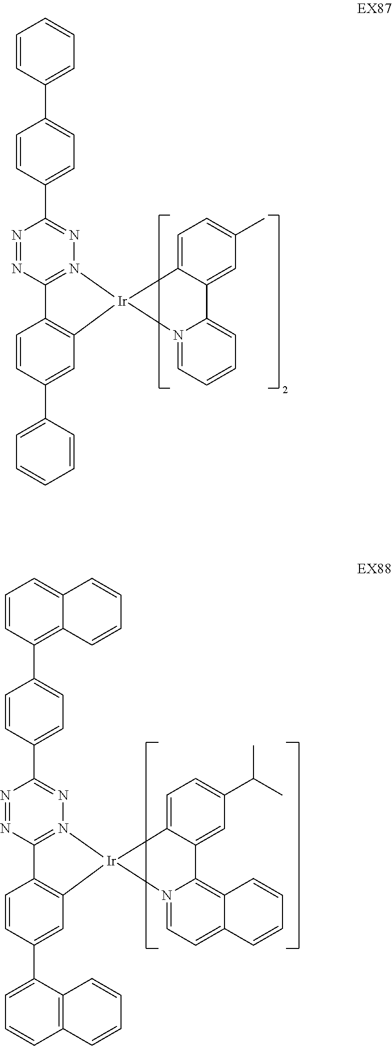

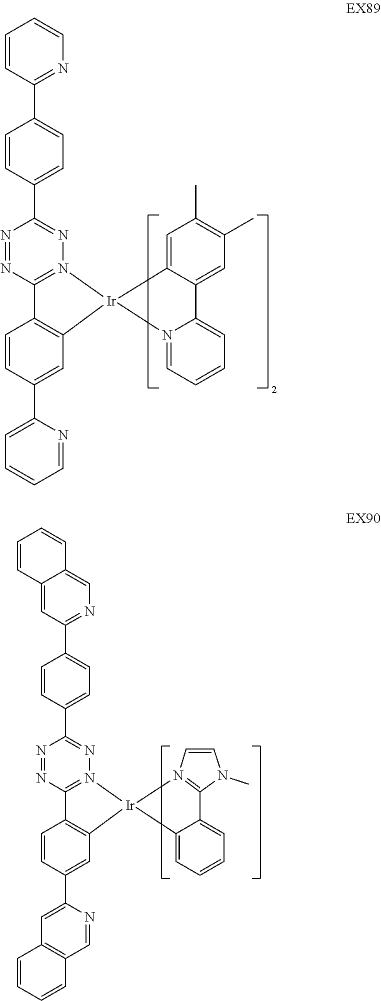

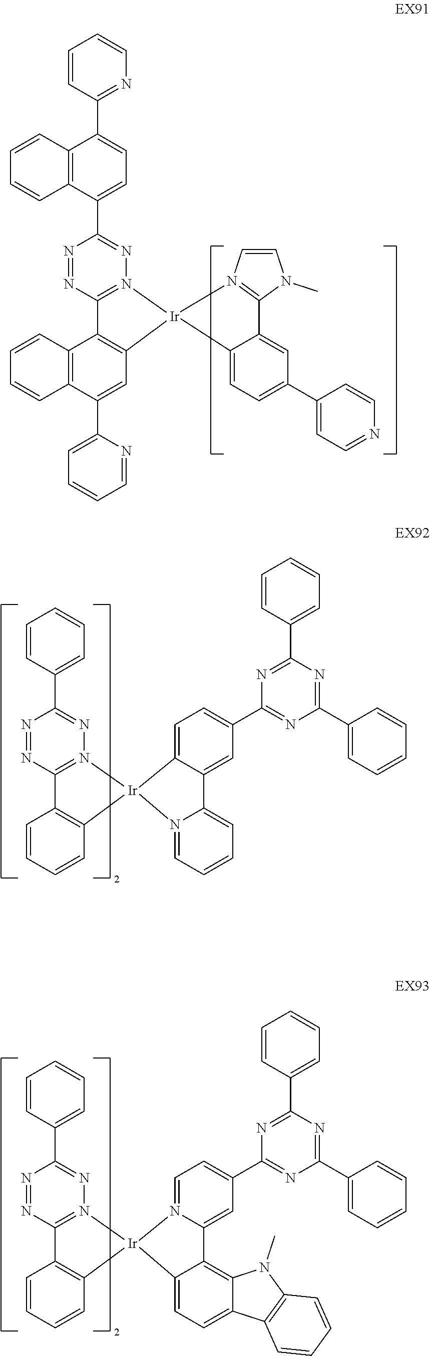

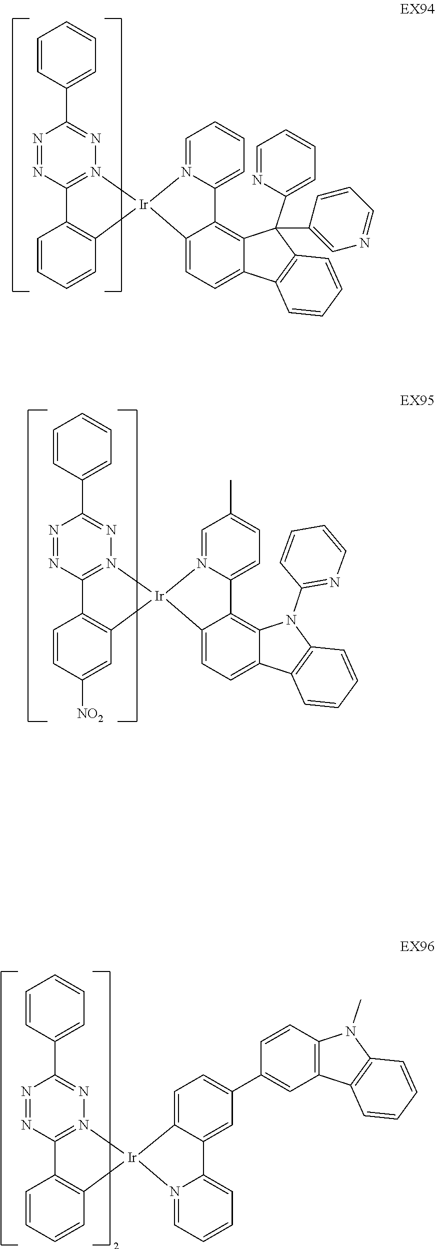

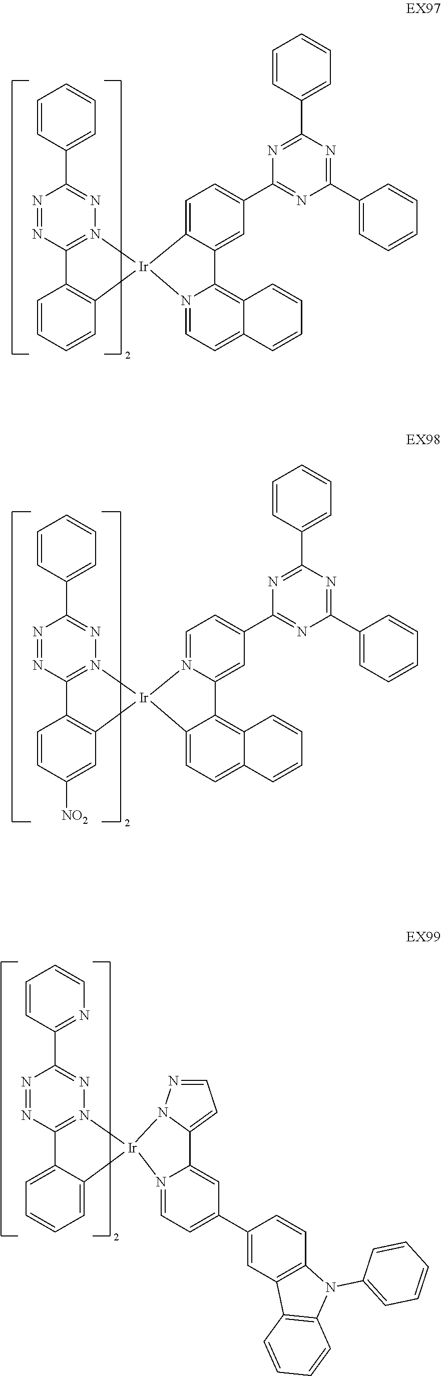

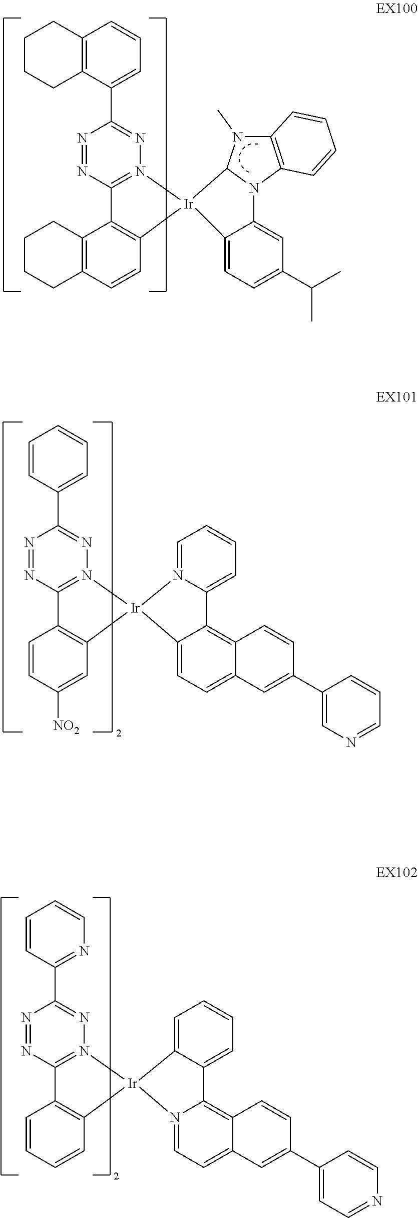

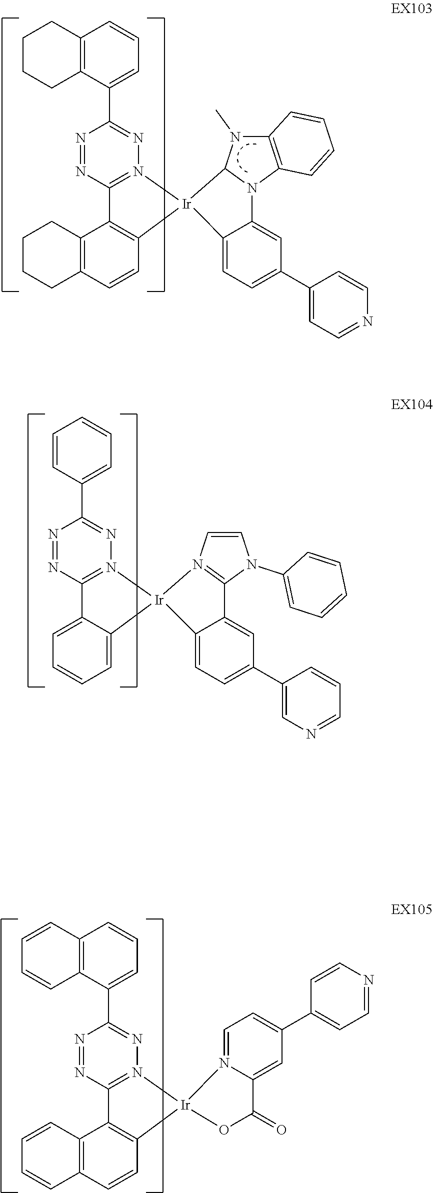

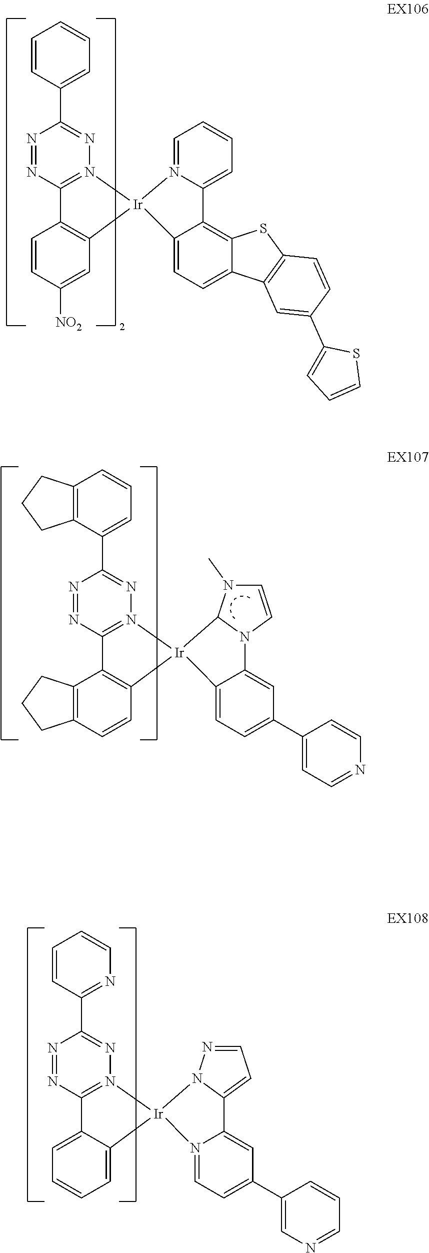

6. An organic electroluminescence device, comprising a pair of electrodes composed of a cathode and an anode, and a light emitting layer between the pair of electrodes, wherein the light emitting layer comprises the iridium complex of claim 1.

7. The organic electroluminescence device of claim 6, wherein the iridium complex of formula (1) is used as a phosphorescent dopant material.

8. The organic electroluminescence device of claim 6, wherein the light emitting layer emits red or yellow phosphorescence.

9. The organic electroluminescence device of claim 6, wherein the organic electroluminescence device is a lighting panel.

10. The organic electroluminescence device of claim 6, wherein the organic electroluminescence device is a backlight panel.
